(19) United States
(12) Patent Application Publication
(10) Pub. No.: US 2016/0020270 A1
(43) Pub. Date: Jan. 21, 2016

(54) METAL-INSULATOR-METAL CAPACITOR, ELECTRONIC DEVICE INCLUDING THE SAME, AND METHOD OF FABRICATING THE SAME

(71) Applicant: SK hynix Inc., Gyeonggi-do (KR)

(72) Inventors: Heon-Joon KIM, Gyeonggi-do (KR); Jae Ho HWANG, Chungcheongbuk-do (KR)

(73) Assignee: SK hynix Inc.

(21) Appl. No.: 14/872,821

(22) Filed: Oct. 1, 2015

Related U.S. Application Data
(63) Continuation-in-part of application No. 14/333,329, filed on Jul. 16, 2014.

(30) Foreign Application Priority Data
Feb. 11, 2014 (KR) 10-2014-0015391
Feb. 27, 2015 (KR) 10-2015-0028624

(51) Int. Cl. H01L 49/02; H01L 27/06

(52) U.S. Cl. CPC H01L 28/60; H01L 27/0629

(57) ABSTRACT

A metal-insulator-metal (MIM) capacitor that includes an insulation pattern on an underlying structure having a capacitor region and a peripheral region surrounding the capacitor region, the insulation pattern having a plurality contact holes that expose portions of the underlying structure in the capacitor region; a lower metal pattern in the capacitor region to cover a top surface of the insulation pattern, sidewalls of the insulation pattern corresponding to sidewalls of the contact holes, and the portions of the underlying structure exposed by the contact holes; a dielectric pattern that covers the lower metal pattern in the capacitor region and a top surface of the insulation pattern in the peripheral region; and an upper metal pattern on the dielectric pattern in the capacitor region and the peripheral region.

### CROSS-REFERENCE TO RELATED APPLICATIONS

The present application is a continuation-in-part of U.S. patent application Ser. No. 14/333,329, filed on Jul. 16, 2014, which claims the priority of Korean Patent Application No. 10-2014-0015391, filed on Feb. 11, 2014 in the Korean Intellectual Property Office. Also, the present application claims the priority of Korean Patent Application No. 10-2015-0028624, filed on Feb. 27, 2015 in the Korean Intellectual Property Office. The disclosures of all of the above applications are incorporated herein in their entirety by reference.

### BACKGROUND

1. Technical Field

Various embodiments of the present disclosure relate to metal-insulator-metal (MIM) capacitors used in a Direct Current-to-Direct Current (DC-to-DC) converter, an electronic device including the same, and a method of fabricating the same.

2. Related Art

Switched power converters used in power supplies are typically categorized as either switched-inductor converters (SICs) or switched-capacitor converters (SCCs). The SICs store energy in their inductors while converting a source of direct current (DC) from one voltage level to another voltage level, and the SCCs may store energy in their capacitors while converting a source of direct current (DC) from one voltage level to another voltage level. The SICs may exhibit a wide operating range and high efficiency. Thus, the SICs have been widely used in application fields requiring high power. However, there may limitations in employing the SICs in compact systems because the SIC inductors occupy a relatively large area. Additionally, the SCCs may be suitable for low power systems having compact size because SCC capacitors occupy a relatively small area as compared with the SIC inductors. The SCCs have been widely used in mobile systems because of their compact size and low electromagnetic interference.

### SUMMARY

Various embodiments are directed to a metal-insulator-metal (MIM) capacitor used in a DC-to-DC converter, an electronic device including the same, and a method of fabricating the same.

According to an embodiment, an MIM capacitor includes a dummy insulation pattern disposed on an underlying structure having a capacitor region and a peripheral region surrounding the capacitor region. The dummy insulation pattern has a plurality contact holes that expose portions of the underlying structure in the capacitor region. A lower metal pattern is disposed on a top surface of the dummy insulation pattern in the capacitor region, sidewalls of the dummy insulation pattern corresponding to sidewalls of the contact holes, and the portions of the underlying structure exposed by the contact holes. The lower metal pattern is disposed to expose a top surface of the dummy insulation pattern in the peripheral region. A dielectric pattern is disposed to cover the lower metal pattern in the capacitor region and to extend from a boundary between the capacitor region and the peripheral region into the peripheral region by a first predetermined distance. An upper metal pattern is disposed on the dielectric pattern in the capacitor region and is disposed to extend from the boundary between the capacitor region and the peripheral region into the peripheral region by a second predetermined distance.

According to an embodiment, an electronic device include a first P-channel MOS transistor, a first N-channel MOS transistor, a second P-channel MOS transistor, a second N-channel MOS transistor, and a capacitor. The first P-channel MOS transistor has a gate electrode connected to a gate voltage input terminal, a source terminal connected to an input voltage terminal, and a drain terminal connected to a first node. The first N-channel MOS transistor has a gate electrode connected to the gate voltage input terminal, a source terminal connected to an output voltage terminal, and a drain terminal connected to the first node. The second P-channel MOS transistor has a gate electrode connected to the gate voltage input terminal, a drain terminal connected to a second node, and a source terminal connected to the output voltage terminal. The second N-channel MOS transistor has a gate electrode connected to the gate voltage input terminal, a drain terminal connected to the second node, and a source terminal connected to a ground terminal. The capacitor is coupled between the first node and the second node. The capacitor includes a dummy insulation pattern, a lower metal pattern, a dielectric pattern, and an upper metal pattern. The dummy insulation pattern is disposed on an underlying structure having a capacitor region and a peripheral region surrounding the capacitor region. The dummy insulation pattern has a plurality contact holes that expose portions of the underlying structure in the capacitor region. The lower metal pattern is disposed on a top surface of the dummy insulation pattern in the capacitor region, sidewalls of the dummy insulation pattern corresponding to sidewalls of the contact holes, and the portions of the underlying structure exposed by the contact holes. The lower metal pattern is disposed to expose a top surface of the dummy insulation pattern in the peripheral region. The dielectric pattern is disposed to cover the lower metal pattern in the capacitor region and to extend from a boundary between the capacitor region and the peripheral region into the peripheral region by a first predetermined distance. The upper metal pattern is disposed on the dielectric pattern in the capacitor region and is disposed to extend from the boundary between the capacitor region and the peripheral region into the peripheral region by a second predetermined distance.

According to an embodiment, an electronic device includes a first complementary metal-oxide-semiconductor (CMOS) inverter, a second CMOS inverter, an insulation layer, a plurality of interconnection patterns, and a capacitor. The first and second CMOS inverters are disposed on a first region of a substrate. The first CMOS inverter includes a first P-channel MOS transistor and a first N-channel MOS transistor, and the second CMOS inverter includes a second P-channel MOS transistor and a second N-channel MOS transistor. The insulation layer is disposed on the substrate to cover the first and second CMOS inverters. The interconnection patterns are disposed in the insulation layer. The capacitor is disposed on a first interconnection pattern of the interconnection patterns and is disposed in the second region. The capacitor includes a dummy insulation pattern, a lower metal pattern, a dielectric pattern, and an upper metal pattern. The dummy insulation pattern is disposed on the first interconnection pattern having a capacitor region and a peripheral region surrounding the capacitor region. The dummy insulation pattern has a plurality contact holes that expose portions of the first interconnection pattern in the capacitor region. The lower metal pattern is disposed on a top surface of the dummy insulation pattern in the capacitor region, sidewalls of the dummy insulation pattern corresponding to sidewalls of the contact holes and the portions of the first interconnection pattern exposed by the contact holes. The lower metal pattern is disposed to expose a top surface of the dummy insulation pattern in the peripheral region. The dielectric pattern is disposed to cover the lower metal pattern in the capacitor region and to extend from a boundary between the capacitor region and the peripheral region into the peripheral region by a first predetermined distance. The upper metal pattern is disposed on the dielectric pattern in the capacitor region and is disposed to extend from the boundary between the capacitor region and the peripheral region into the peripheral region by a second predetermined distance. A drain terminal and a source terminal of the first P-channel MOS transistor are respectively connected to the first interconnection pattern and an input voltage terminal. A drain terminal and a source terminal of the first N-channel MOS transistor are respectively connected to the first interconnection pattern and an output voltage terminal. A source terminal and a drain terminal of the second P-channel MOS transistor are respectively connected to the output voltage terminal and the upper metal pattern of the capacitor. A source terminal and a drain terminal of the second N-channel MOS transistor are respectively connected to a ground terminal and the upper metal pattern of the capacitor. Gate electrodes of the first and second P-channel MOS transistors and gate electrodes of the first and second N-channel MOS transistors are electrically connected to a gate voltage input terminal.

According to another embodiment, an electronic device includes a first complementary metal-oxide-semiconductor (CMOS) inverter, a second CMOS inverter, an insulation layer, a plurality of interconnection patterns, and a capacitor. The first and second CMOS inverters are disposed on a substrate. The first CMOS inverter includes a first P-channel MOS transistor and a first N-channel MOS transistor, and the second CMOS inverter includes a second P-channel MOS transistor and a second N-channel MOS transistor. The insulation layer is disposed on the substrate to cover the first and second CMOS inverters. The interconnection patterns are disposed in the insulation layer. The capacitor is disposed on a first interconnection pattern of the interconnection patterns and is disposed in the insulation layer. The capacitor includes a dummy insulation pattern, a lower metal pattern, a dielectric pattern, and an upper metal pattern. The dummy insulation pattern is disposed on the first interconnection pattern having a capacitor region and a peripheral region surrounding the capacitor region. The dummy insulation pattern has a plurality contact holes that expose portions of the first interconnection pattern in the capacitor region. The lower metal pattern is disposed on a top surface of the dummy insulation pattern in the capacitor region, sidewalls of the dummy insulation pattern corresponding to sidewalls of the contact holes, and the portions of the first interconnection pattern exposed by the contact holes. The lower metal pattern is disposed to expose a top surface of the dummy insulation pattern in the peripheral region. The dielectric pattern is disposed to cover the lower metal pattern in the capacitor region and to extend from a boundary between the capacitor region and the peripheral region into the peripheral region by a first predetermined distance. The upper metal pattern is disposed on the dielectric pattern in the capacitor region and is disposed to extend from the boundary between the capacitor region and the peripheral region into the peripheral region by a second predetermined distance. A drain terminal and a source terminal of the first P-channel MOS transistor are respectively connected to the first interconnection pattern and an input voltage terminal. A drain terminal and a source terminal of the first N-channel MOS transistor are respectively connected to the first interconnection pattern and an output voltage terminal. A source terminal and a drain terminal of the second P-channel MOS transistor are respectively connected to the output voltage terminal and the upper metal pattern of the capacitor. A source terminal and a drain terminal of the second N-channel MOS transistor are respectively connected to a ground terminal and the upper metal pattern of the capacitor. Gate electrodes of the first and second P-channel MOS transistors and gate electrodes of the first and second N-channel MOS transistors are electrically connected to a gate voltage input terminal.

According to another embodiment, there is provided method of fabricating an MIM capacitor. The method includes forming a dummy insulation pattern on an underlying structure having a capacitor region and a peripheral region surrounding the capacitor region. The dummy insulation pattern is formed to have a plurality of contact holes exposing portions of the underlying structure. A lower metal pattern is formed on a top surface of the dummy insulation pattern, the portions of the underlying structure exposed by the contact holes, and sidewalls of the underlying structure exposed by the contact holes. The lower metal pattern is formed in the capacitor region to expose a top surface of the dummy insulation pattern in the peripheral region. A dielectric layer is formed on the lower metal pattern in the capacitor region and the dummy insulation pattern in the peripheral region. An upper metal layer is formed on the dielectric layer. The upper metal layer and the dielectric layer are sequentially patterned to form an upper metal pattern and a dielectric pattern. The dielectric pattern is formed to cover the lower metal pattern in the capacitor region and to extend from a boundary between the capacitor region and the peripheral region into the peripheral region by a predetermined distance. The upper metal pattern is formed on the dielectric pattern in the capacitor region to extend from the boundary between the capacitor region and the peripheral region into the peripheral region by the predetermined distance.

### BRIEF DESCRIPTION OF THE DRAWINGS

Various embodiments of the present disclosure will become more apparent in view of the attached drawings and accompanying detailed description, in which:

FIG. 1 is a cross-sectional view exemplarily illustrating a DC-to-DC converter in accordance with an embodiment;

FIG. 2 is a cross-sectional view exemplarily illustrating a DC-to-DC converter in accordance with an embodiment;

FIGS. 3A to 3K are cross-sectional views exemplarily illustrating a method for fabricating the DC-to-DC converter shown in FIG. 1;

FIG. 4 is a cross-sectional view illustrating an MIM capacitor according to an embodiment;

FIG. 5 is a plan view illustrating a meta layer and a dummy insulation pattern of the MIM capacitor shown in FIG. 4;

FIG. 6 is a plan view illustrating a lower metal pattern of the MIM capacitor shown in FIG. 4;

FIG. 7 is a plan view illustrating a dielectric pattern of the MIM capacitor shown in FIG. 4;

FIG. 8 is a plan view illustrating an upper metal pa of the MIM capacitor shown in FIG. 4;

FIGS. 9 to 22 are perspective views and cross-sectional views illustrating a method of fabricating an MIM capacitor according to an embodiment;

FIG. 23 is a circuit diagram illustrating a switched-capacitor converter (SCC) employing an MIM capacitor;

FIG. 24 is a cross-sectional view illustrating an example of the SCC shown in FIG. 23; and

FIG. 25 is a cross-sectional view illustrating another example of the SCC shown in FIG. 23.

### DETAILED DESCRIPTION OF THE EMBODIMENTS

It will be understood that although the terms first, second, third etc. may be used herein to describe various elements, these elements are not limited by these terms. These terms are only used to distinguish one element from another element. Thus, a first element in some embodiments could be termed a second element in other embodiments without departing from the teachings of the present disclosure.

It will also be understood that when an element is referred to as being located “under”, “beneath,” “below”, “lower, on”, “over”, “above,” “upper”, “side” or “aside” another element, it can be directly contact the other element, or at least one intervening element may also be present therebetween. Accordingly, the terms such as “under”, “beneath,” “below”, “lower,” “on”, “over”, “above,” “upper”, “side” “aside” and the like which are used herein are for describing particular embodiments only and are not intended to limit the scope of the present disclosure. Other words used to describe the relationship between elements or layers should be interpreted in a like fashion (e.g., “between” versus “directly between” or “adjacent” versus “directly adjacent”).

It will be further understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

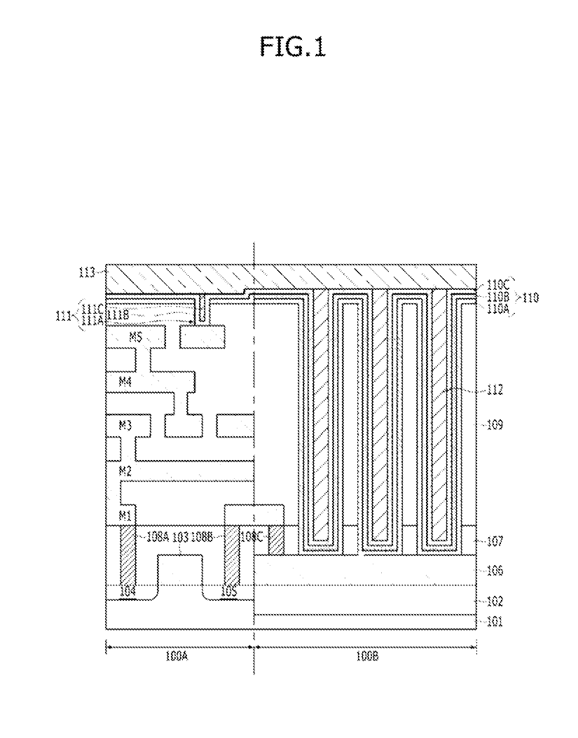

FIG. 1 is a cross-sectional view exemplarily illustrating a DC-to-DC converter in accordance with an embodiment.

Referring to FIG. 1, an isolation layer 102 is formed ire a substrate 101. The substrate 101 includes a first region (e.g., an active region) 100A which is defined by the isolation layer 102 and a second region (e.g. an isolation region) 100B in which the isolation layer 102 is formed. The first region 100A may include a switching element region, and the second region 100B may include a capacitor region. The substrate 101 may include a silicon substrate, a silicon-germanium (SiGe) substrate or a silicon-on-insulator (SOI) substrate.

A switching element is formed over the substrate 101 of the first region 100A. The switching element includes a transistor. The transistor includes a gate electrode 103, a source region 104 and a drain region 105. A sidewall spacer (not shown) may be formed on the sidewalls of the gate electrode 103. The gate electrode 103 may include a silicon-containing layer. For example, the gate electrode 103 may include a poly-silicon layer. The gate electrode 103 may be formed of an undoped silicon layer which is not doped with any impurity or a doped silicon layer which is doped with an impurity.

A landing plate 106 is formed over the substrate 101 of the first region 100B. The landing plate 106 may be disposed at the same surface level as the gate electrode 103 of the transistor. The landing plate 106 is formed of the same material as the gate electrode 103.

A first inter-layer insulation layer 107 is formed to cover the first region 100A and the second region 100B. The first inter-layer insulation layer 107 includes a plurality of contact plugs. The contact plugs include a first contact plug 108A, a second contact plug 108B and a third contact plug 108C. The first contact plug 108A may be coupled with the source region 104, and the second contact plug 108B may be coupled with the drain region 105, and the third contact plug 108C may be coupled with the landing plate 106. The first inter-layer insulation layer 107 may be one selected from the group consisting of an oxide layer, a nitride layer and an oxynitride layer. The first inter-layer insulation layer 107 may include an oxide layer. The contact plugs may include a metal layer, a metal nitride layer, a noble metal layer, a heat-resisting metal layer, a poly-silicon, etc.

A second inter-layer insulation layer 109 is formed over the first inter-layer insulation layer 107. The second inter-layer insulation layer 109 of the first region 100A includes multi-layer metal lines. The multi-layer metal lines are formed in the upper portion of the transistor. The multi-layer metal lines are selectively coupled by a metal contact. The multi-layer metal lines include at least the lowermost metal line and the uppermost metal line. For example, the multi-layer metal lines include a first metal line M1, a second metal line M2, a third metal line M3, a fourth metal line M4 and a fifth metal line M5. The first metal line M1 may be the lowermost metal line, and the fifth metal line M5 may be the uppermost metal line. The first metal line M1 is coupled with the contact plugs. The first metal line M1 which is coupled with the second contact plug 108B and the third contact plug 108C may be referred to as a first interconnection portion which couples the landing plate 106 with the transistor.

A capacitor 110 is formed over the landing plate 106 of the second region 100B. The capacitor 110 includes a cylindrical bottom plate 110A, a dielectric layer 110B and a top plate 110C. The bottom plate 110A has a structure of being coupled with the landing plate 106 in the form of continuum and extended to a boundary line between the first region 100A and the second region 100B. The dielectric layer 110B has a structure of being extended to overlap with the upper portions of the multi-layer metal lines. The bottom plate 110A and the top plate 110C include a titanium-containing layer. The bottom plate 110A and the top plate 110C may be formed of one selected from the group consisting of a titanium layer and a titanium nitride layer. For example, the bottom plate 110A and the top plate 110C may include a titanium nitride layer. This is due to stack coverage being superior. The dielectric layer 1103 includes a high-k material. The high-k material may be one selected from the group consisting of hafnium dioxide (HfO₂), zirconium dioxide (ZrO₂), titanium dioxide (TiO₂) tantalum pentoxide (TA₂O₅) and strontium titanate STO(SrTiO₃). The dielectric layer 1103 may be a single layer of one selected from the group or a stacked layer thereof. For example, the dielectric layer 1103 may be a zirconium dioxide layer (ZrO₂).

A second interconnection portion is formed to couple the fifth metal line M5 with the top plate 110C. The second interconnection portion includes a via 111 formed over the fifth metal line M5, a second via plug 112 formed over the capacitor 110, and interconnection lines 113 formed over the via 111 and the second via plug 112. The via 111 includes a via hole 111A, a barrier metal 1113 formed in the via hole 111A, and a first via plug 111C formed over the barrier metal 111B. The barrier metal 111B has a structure where it is extended continuously to the fifth metal line M5 from the top plate 110C of the capacitor 110. The first via plug 111C and the second via plug 112 may be formed of a metallic layer. The metallic layer may include a metal layer, a metal oxide layer, metal nitride layer, etc. For example, the first via plug 111C and the second via plug 112 may include a tungsten layer. The interconnection lines 113 may include the same material as the multi-layer metal lines.

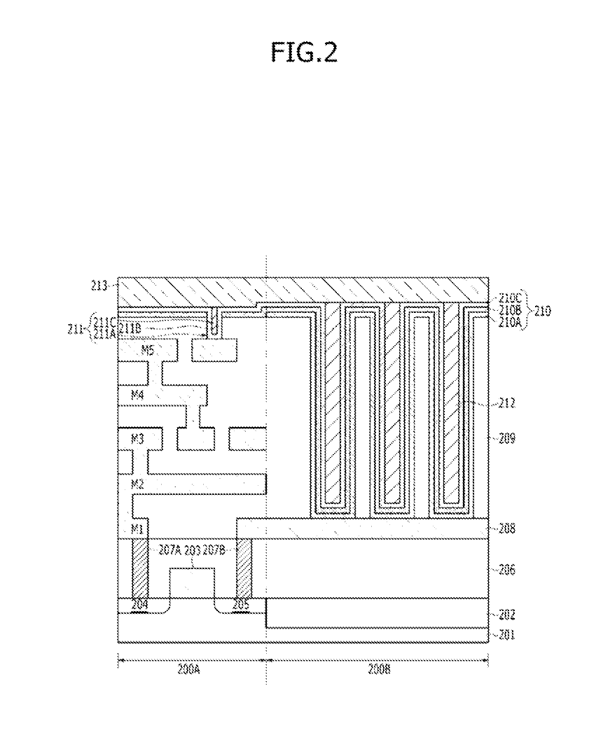

FIG. 2 is a cross-sectional view exemplarily illustrating a DC-to-DC converter in accordance with an embodiment.

Referring to FIG. 2, an isolation layer 202 is formed in a substrate 201. The substrate 201 includes a first region 200A which is defined by the isolation layer 202 and a second region 200B in which the isolation layer 202 is formed. The first region 200A may include a switching element region, and the second region 200B may include a capacitor region. The substrate 201 may include a silicon substrate, a silicon-germanium (SiGe) substrate or an SOI substrate.

A transistor is formed over the substrate 201 of the first region 200A. The transistor includes a gate electrode 203, a source region 204 and a drain region 205. A sidewall spacer (not shown) may be formed on the sidewalls of the gate electrode 203. The gate electrode 203 may include a silicon-containing layer. For example, the gate electrode 203 may include a poly-silicon layer. The gate electrode 203 may be formed of an undoped silicon layer which is not doped with any impurity or a doped silicon layer which is doped with an impurity.

A first inter-layer insulation layer 206 is formed to cover the first region 200A and the second region 200B. The first inter-layer insulation layer 205 includes a plurality of contact plugs. The contact plugs include a first contact plug 207A and a second contact plug 2078. The first contact plug 207A may be coupled with the source region 204, and the second contact plug 2076 may be coupled with the drain region 205. The first inter-layer insulation layer 206 may be one selected from the group consisting of an oxide layer, a nitride layer and an oxynitride layer. The first inter-layer insulation layer 206 may include an oxide layer. The contact plugs may include a metal layer, a metal nitride layer, a noble metal layer, a heat-resisting metal layer, a poly-silicon, etc.

A second inter-layer insulation layer 209 is formed over the first inter-layer insulation layer 206. The second inter-layer insulation layer 209 of the first region 200A includes multi-layer metal lines. The multi-layer metal lines are formed in the upper portion of the transistor. The multi-layer metal lines are selectively coupled by a metal contact. The multi-layer metal lines include at least the lowermost-layer metal line and the uppermost metal line. For example, the multi-layer metal lines include a first metal line M1, a second metal line M2, a third metal line M3, a fourth metal line M4 and a fifth metal line M5. The first metal line M1 may be the lowermost metal line, and the fifth metal line M5 may be the uppermost metal line.

A landing plate 208 is formed over the first inter-layer insulation layer 206 of the first region 200B. The landing plate 208 may be disposed at the same surface level as the first metal line M1. The landing plate 208 may be coupled with the second contact plug 2076. The landing plate 208 is formed of the same material as the multi-layer metal lines.

A capacitor 210 is formed over the landing plate 208 of the second region 200B. The capacitor 210 includes a cylindrical bottom plate 210A, a dielectric layer 210B and a top plate 210C. The capacitor 210 may be formed around the multi-layer metal lines. The bottom plate 210A has a structure of being coupled with the landing plate 208 in the form of continuum and extended to a boundary line between the first region 200A and the second region 200B. The dielectric layer 210B has a structure of being extended to overlap with the upper portions of the multi-layer metal lines. The bottom plate 210A and the top plate 210C include a titanium-containing layer. The bottom plate 210A and the top plate 210C may be formed of one selected from the group consisting of a titanium layer and a titanium nitride layer. For example, the bottom plate 210A and the top plate 210C may include a titanium nitride layer. This is due to stack coverage being superior. The dielectric layer 210B includes a high-k material. The high-k material may be formed of one selected from the group consisting of hafnium dioxide (HfO₂), zirconium dioxide (ZrO₂), titanium dioxide (TiO₂), tantalum pentoxide (TA₂O₅) and strontium titanate STO(SrTiO₃). The dielectric layer 2106 may be a single layer of one selected from the group or a stacked layer thereof. For example, the dielectric layer 210B may be a zirconium dioxide layer (ZrO₂).

An interconnection portion is formed to couple the fifth metal line M5 with the top plate 210C. The interconnection portion includes a via 211 formed over the fifth metal line M5, a second via plug 212 formed over the capacitor 210, and interconnection lines 213 formed over the via 211 and the second via plug 212. The via 211 includes a via hole 211A, a barrier metal 211B formed in the via hole 211A, and a first via plug 211C formed over the barrier metal 211B. The barrier metal 211B has a structure where it is extended continuously to the fifth metal line M5 from the top plate 210C of the capacitor 210. The first via plug 211C and the second via plug 212 may be formed of a metallic layer. The metallic layer may include a metal layer, a metal oxide layer, metal nitride layer, etc. For example, the first via plug 211C and the second via plug 212 may include a tungsten layer. The interconnection lines 213 may include the same material as the multi-layer metal lines.

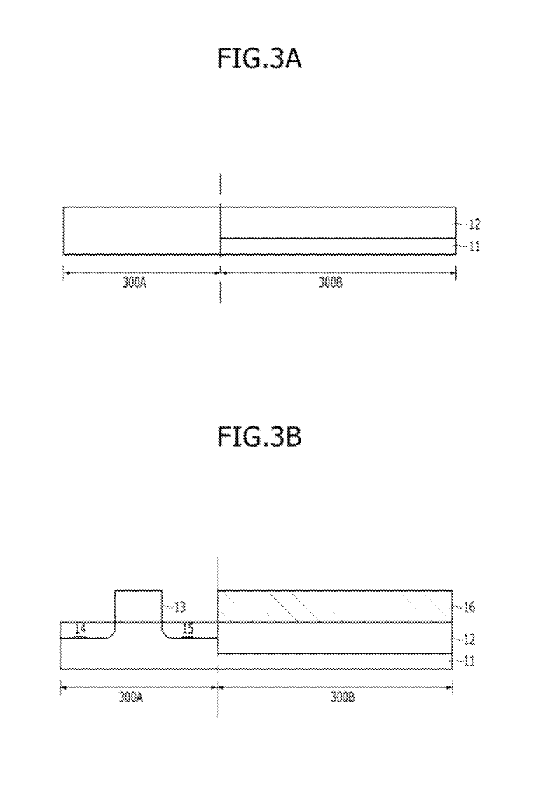

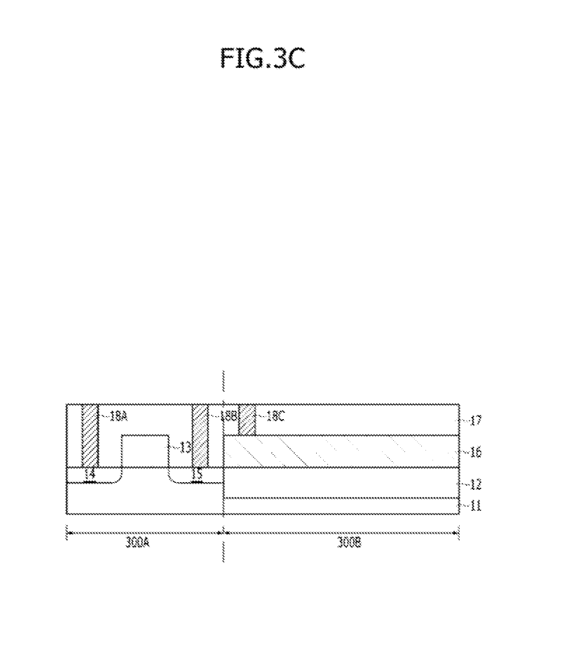

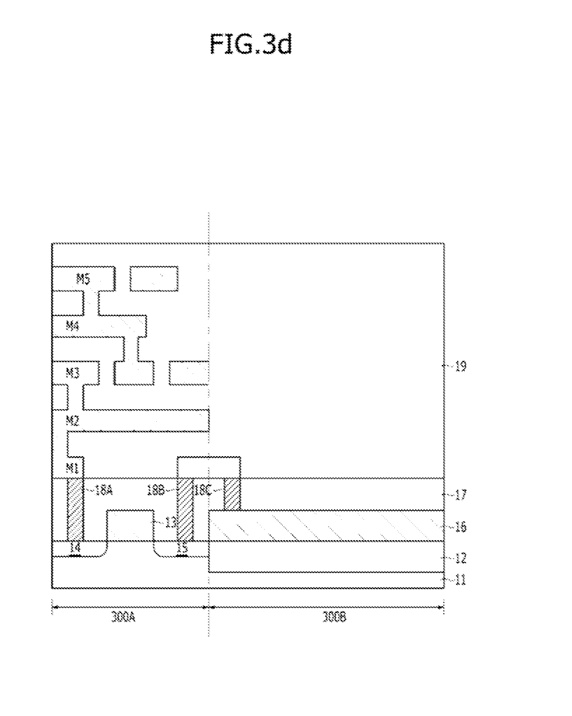

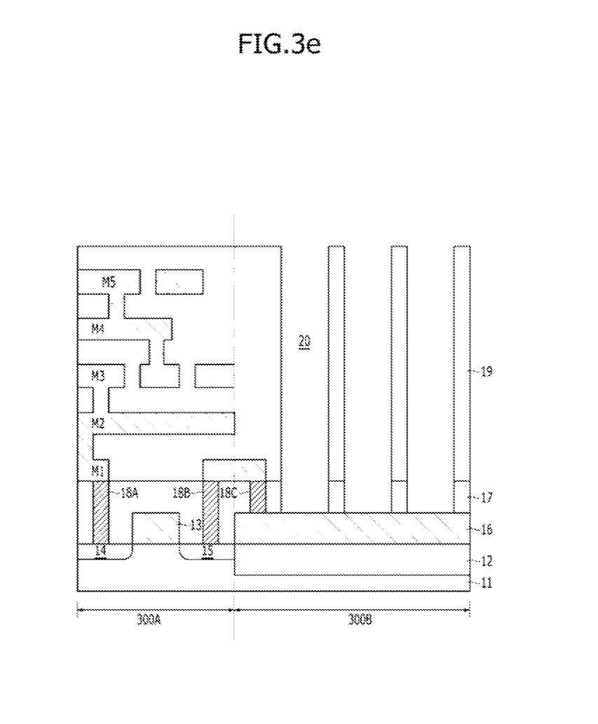

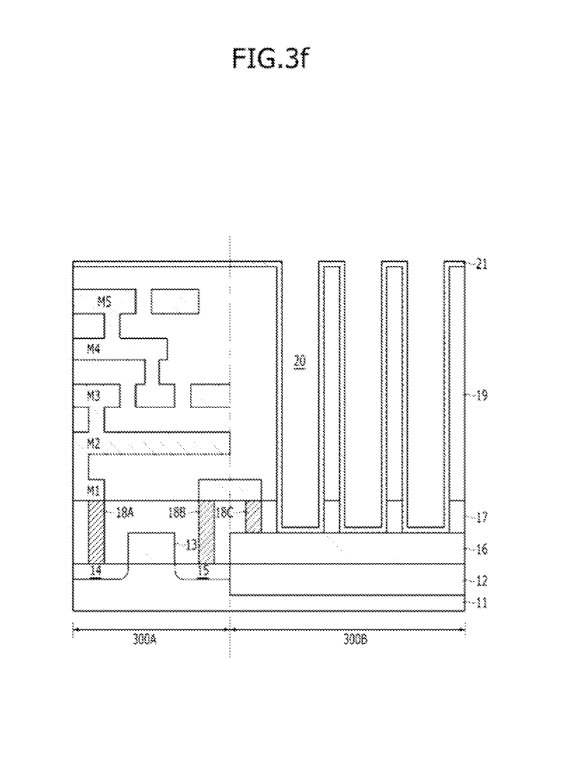

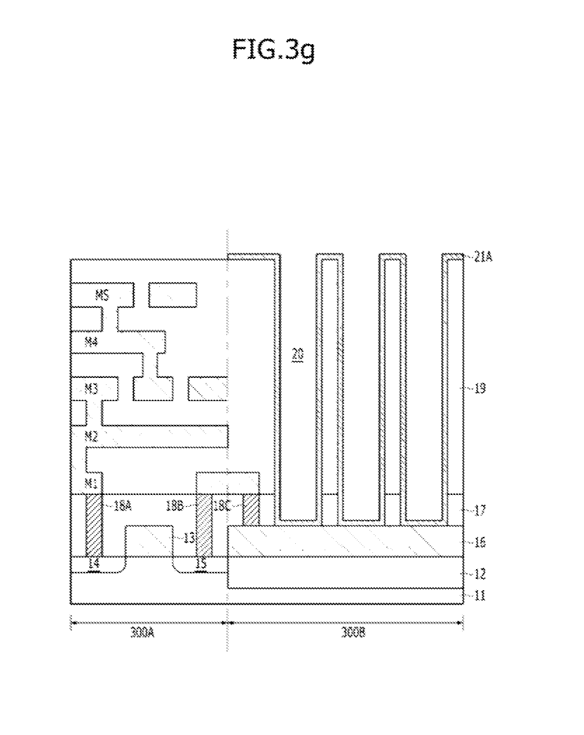

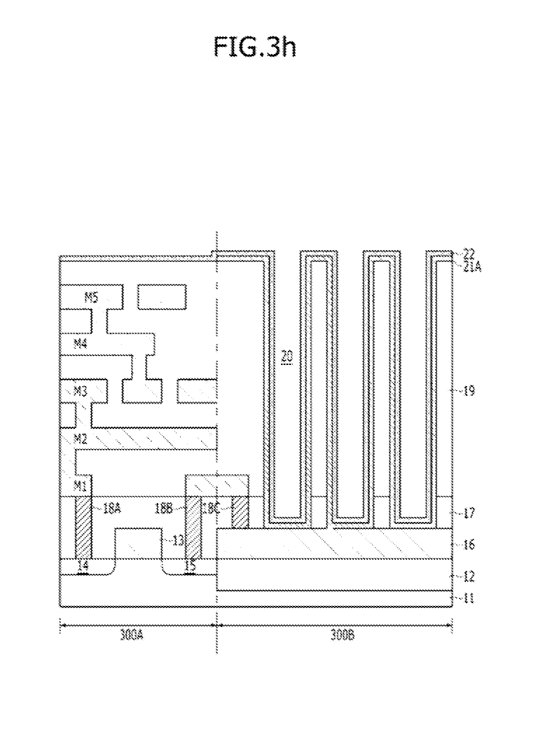

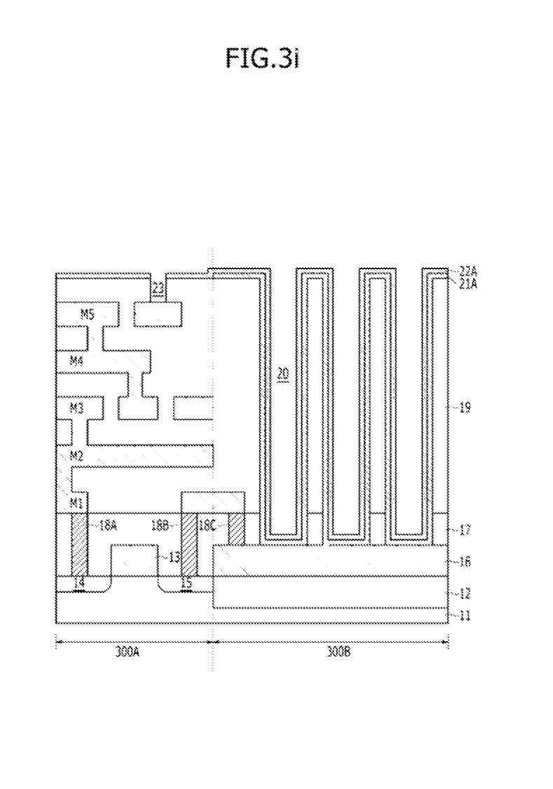

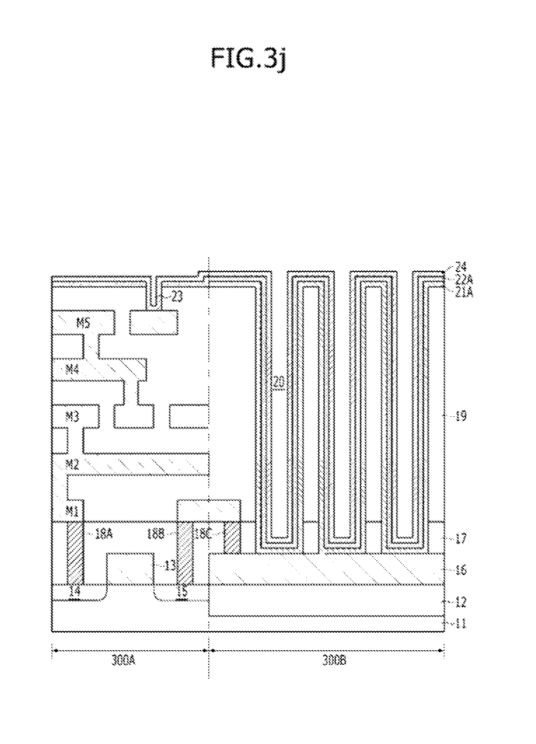

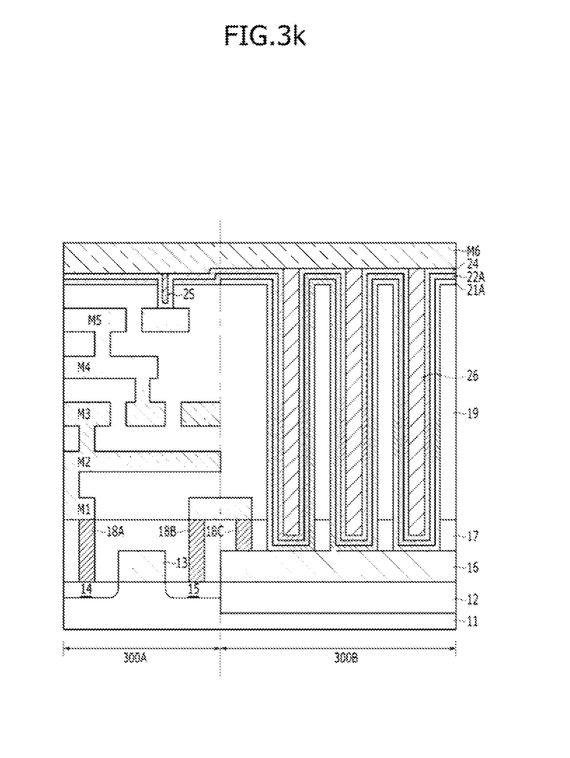

FIGS. 3A to 3K are cross-sectional views exemplarily illustrating a method for fabricating the DC-to-DC converter shown in FIG. 1.

Referring to FIG. 3A, an isolation layer 12 is formed in a substrate 11. The substrate 11 includes a first region 300A which is defined by the isolation layer 12 and a second region 300B in which the isolation layer 12 is formed. The first region 300A may include a switching element region, and the second region 300B may include a capacitor region. The substrate 11 includes a semiconductor substrate 11. The semiconductor substrate 11 may include a silicon substrate, a silicon-germanium (SiGe) substrate or an SOI substrate. The isolation layer 12 may be formed through a Shallow Trench Isolation (STI) process.

Referring to FIG. 3B, a transistor is formed over the substrate 11 of the first region 300A. The transistor includes a gate electrode 13, a source region 14 and a drain region 15. In order to form the transistor, a first conductive layer (not shown) is formed over the substrate 11. The first conductive layer may include a silicon-containing layer. For example, the first conductive layer may include a poly-silicon layer. The first conductive layer may be formed of an undoped silicon layer which is not doped with any impurity or a doped silicon layer which is doped with an impurity. Subsequently, a first hard mask (not shown) is formed over the first conductive layer. A first hard mask pattern is formed by patterning the first hard mask through a sensitive layer (not shown). A gate electrode 13 is formed by etching the first conductive layer using the first hard mask pattern as an etch barrier.

When the gate electrode 13 is formed, a landing plate 16 is formed over the substrate 11 of the second region 300B. The landing plate 16 may be formed simultaneously with the gate electrode 13. The landing plate 16 includes the same material as the gate electrode 13. After the gate electrode 13 and the landing plate 16 are formed, the high-concentration source region 14 and drain region 15 are formed.

Referring to FIG. 3C, a first inter-layer dielectric layer 17 is formed over the substrate 11. The first inter-layer dielectric layer 17 may be one selected from the group consisting of an oxide layer, a nitride layer and an oxynitride layer. The first inter-layer dielectric layer 17 may include an oxide layer. The first inter-layer dielectric layer 17 includes a plurality of contact plugs. For example, the contact plugs include a first contact plug 18A, a second contact plug 18B and a third contact plug 18C. The first contact plug 18A may be coupled with the source region 14, and the second contact plug 18B may be coupled with the drain region 15, and the third contact plug 18C may be coupled with the landing plate 16. To form the contact plugs, a plurality of contact holes (not shown) are formed in the first inter-layer dielectric layer 17. After a conductive layer is formed in the contact holes, the contact plugs may be formed by planarizing the conductive layer to expose the upper portion of the first inter-layer dielectric layer 17. The contact plugs may include a metal layer, a metal nitride layer, a noble metal layer, a heat-resisting metal layer, a poly-silicon, etc.

Referring to FIG. 3D, a second inter-layer insulation layer 19 including multi-layer metal lines is formed. The multi-layer metal lines may be formed in the upper portion of the transistor of the first region 300A. The multi-layer metal lines are selectively coupled by a metal contact. The multi-layer metal lines include at least the lowermost metal line and the uppermost metal line. For example, the multi-layer metal lines include a first metal line M1, a second metal line M2, a third metal line M3, a fourth metal line M4 and a fifth metal line M5. The first metal line M1 may be the lowermost metal line, and the fifth metal line M5 may be the uppermost metal line. The first metal line M1 is formed over the first to third contact plugs 18A to 18C. The landing plate 16 may be coupled with the transistor by the first metal line M1 which is coupled with the second and third contact plugs 18B and 18C.

The second inter-layer insulation layer 19 may be one selected from the group consisting of an oxide layer, a nitride layer and an oxynitride layer. The second inter-layer insulation layer 19 may include an oxide layer. The thickness of the second inter-layer insulation layer 19 may be controlled based on capacitance which is required for a capacitor to be formed through a subsequent process. Since the height of the capacitor is determined based on the thickness of the second inter-layer insulation layer 19, the thickness of the second inter-layer insulation layer 19 may be controlled to form the capacitor having the required capacitance. Therefore, a high capacitor may be formed.

Referring to FIG. 3E, a plurality of openings 20 are formed in the first and second inter-layer insulation layers 17 and 19 of the second region 300B. The openings 20 may expose the landing plate 16 by selectively etching the first and second inter-layer insulation layers 17 and 19. The etch process for forming the openings 20 may include a dry etch process. The sidewalls of the openings 20 may have a vertical profile or an inclined profile. Each opening 20 is a three-dimensional (3D) structure in which a lower electrode of the capacitor is formed through a subsequent process.

Referring to FIG. 3F, a second conductive layer 21 is formed over the structure including the openings 20. The second conductive layer 21 is formed to have such a thickness that it does not gap-fill the openings 20. The second conductive layer 21 includes a titanium-containing layer. The second conductive layer 21 may be formed of one selected from the group consisting of a titanium layer and a titanium nitride layer. For example, the second conductive layer 21 may include a titanium nitride layer. This is due to stack coverage being superior. The second conductive layer 21 may be formed through an Atomic Layer Deposition (ALD) process or a Chemical Vapor Deposition (CVD) process.

A second hard mask pattern (not shown) is formed over the second conductive layer 21 of the second region 300B. The second hard mask pattern may be formed by patterning the second hard mask through a sensitive layer (not shown).

Referring to FIG. 3G, the second conductive layer 21 of the first region 300A is etched using the second hard mask pattern as an etch barrier. As a result, a bottom plate 21A is formed in the second region 300B. The bottom plate 21A may have a successive cylindrical shape. The bottom plate 21A is formed in the second region 3006 so as to stably block the landing plate 16 and a top plate 24 to be formed through a subsequent process.

Referring to FIG. 3H, a dielectric layer 22 is formed over the structure including the bottom plate 21A. The dielectric layer 22 is formed to have such a thickness that it does not gap-fill the openings 20. The dielectric layer 22 includes a high-k material. The high-k material may be one selected from the group consisting of hafnium dioxide (HfO₂), zirconium dioxide (ZrO₂), titanium dioxide (TiO₂), tantalum pentoxide (TA₂O₅) and strontium titanate STO(SrTiO₃). The dielectric layer may be a single layer of one selected from the group or a stacked layer thereof. For example, the dielectric layer 22 may be a zirconium dioxide layer (ZrO₂). The dielectric layer 22 is formed using an Atomic Layer Deposition (ALD) process which has excellent step coverage characteristics.

Referring to FIG. 3I, a dielectric layer pattern 22A is formed. The dielectric layer pattern 22A may be formed by patterning the dielectric layer 22 through a sensitive layer (not shown). The dielectric layer pattern 22A of the first region 300A may be used as a hard mask for forming a via hole. The second inter-layer insulation layer 19 of the first region 300A is etched using the dielectric layer pattern 22A of the first region 300A as an etch barrier and a via hole 23 may be formed. The via hole 23 may expose the surface of the fifth metal line M5.

Referring to FIG. 3J, the top plate 24 is formed over the structure including the via hole 23 and the openings 20. The top plate 24 is formed to have such a thickness that it does not gap-fill the via hole 23 and the openings 20. The top plate 24 may conformally cover the surface of the structure including the via hole 23 and the openings 20. The top plate 24 includes a titanium-containing layer. The top plate 24 may be formed of one selected from the group consisting of a titanium layer and a titanium nitride layer. For example, the top plate 24 may include a titanium nitride layer. The top plate 24 may be formed using an Atomic Layer Deposition (ALD) process or a Chemical Vapor Deposition (CVD) process. The top plate 24 formed in the via hole 23 of the first region 300A may be used as a barrier metal.

A capacitor is formed where the bottom plate 21A coupled sequentially with the landing plate 16 of the second region 300B, the dielectric layer formed over the bottom plate 21A, and the top plate 24 formed over the dielectric layer are stacked.

Referring to FIG. 3K, a third conductive layer which covers the first and second regions 300A and 300B is formed. Subsequently, a planarization process is performed on the third conductive layer until the surface of the top plate 24 is exposed. The planarization process may be performed using a Chemical Mechanical Polishing (CMP) process. As a result, a plurality of plugs may be formed to gap-fill the via hole 23 and the openings 20. The plugs include a first via plug 25 of the first region 300A and a second via plug 26 of the second region 300B. The plugs may be formed of a metallic layer. The metallic layer may include a metal layer, a metal oxide layer, a metal nitride layer, etc. For example, the plugs may include a tungsten layer.

A sixth metal line M6 is formed to cover the first and second regions 300A and 300B. The sixth metal line M6 includes the same material as the multi-layer metal lines. The transistor and the capacitor may be electrically connected to each other by forming the sixth metal lines M.

In accordance with the embodiments, the size of an occupying area in a device may be reduced as a cylindrical capacitor is formed around multi-layer metal lines.

In accordance with the embodiments, capacitance may increase as a successive cylindrical capacitor is formed over a landing plate.

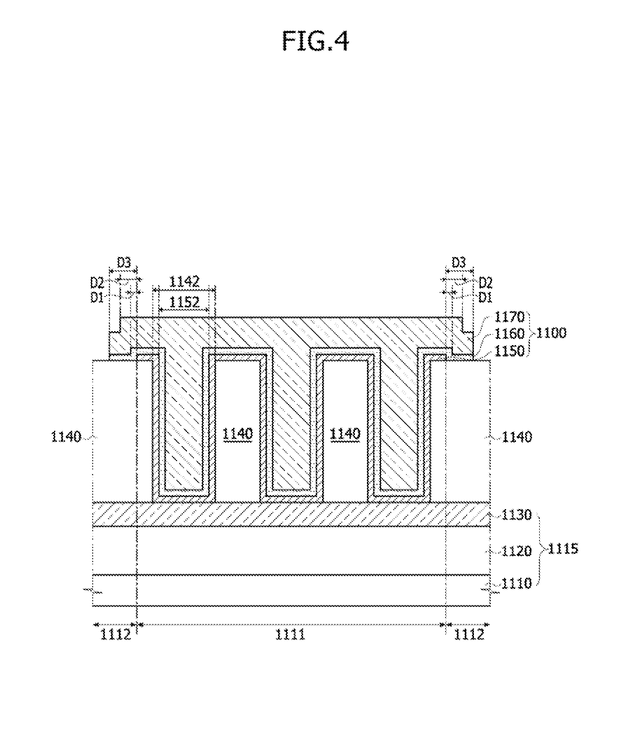

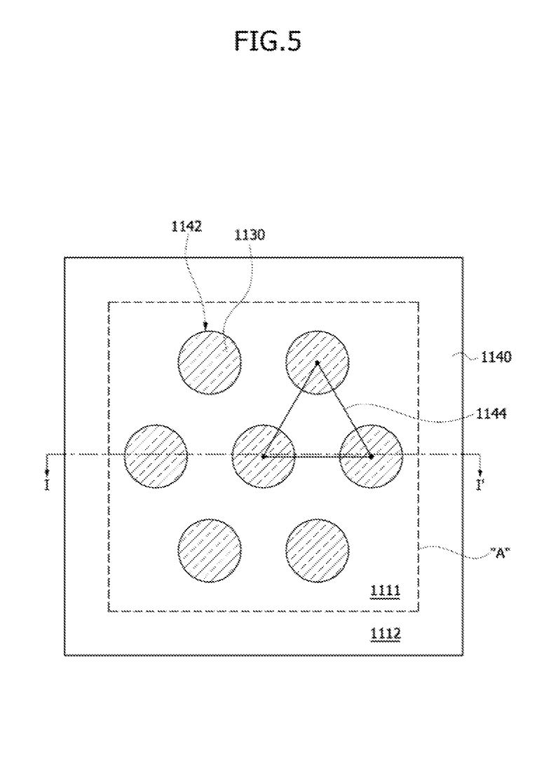

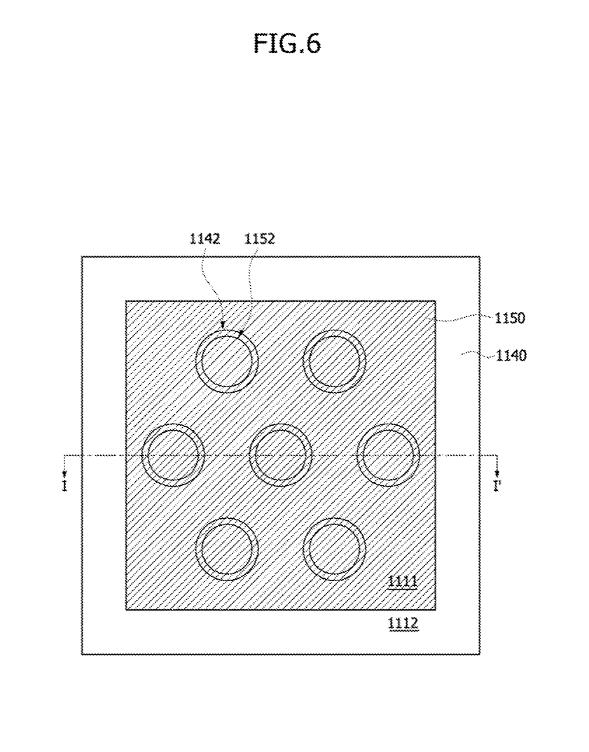

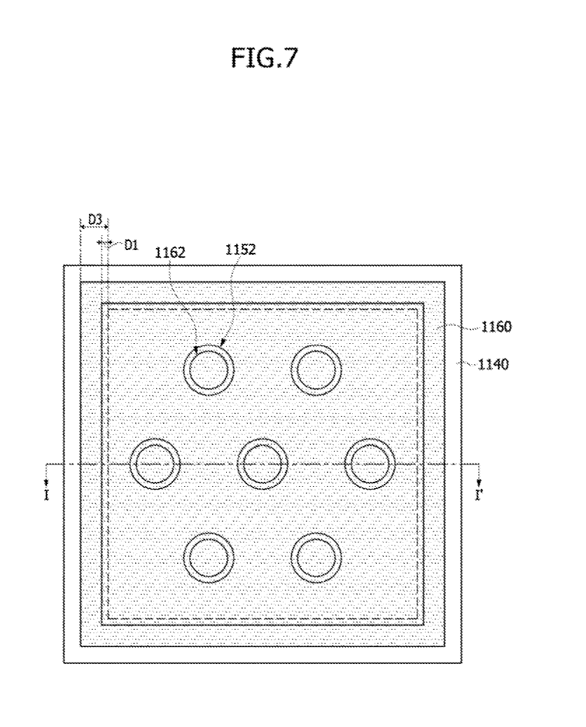

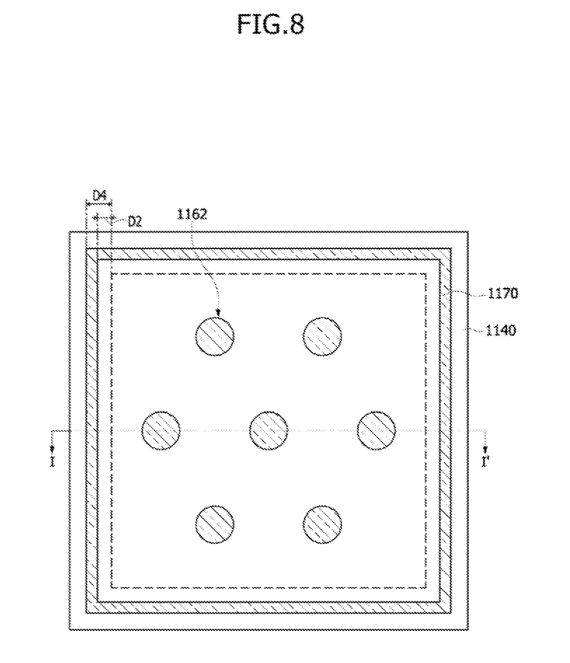

FIG. 4 is a cross-sectional view illustrating an MIM capacitor 1100 according to an embodiment. FIG. 5 is a plan view illustrating a metal layer and a dummy insulation pattern of the MIM capacitor 1100 shown in FIG. 4. FIG. 6 is a plan view illustrating a lower metal pattern of the MIM capacitor 1100 shown in FIG. 4. FIG. 7 is a plan view illustrating a dielectric pattern of the MIM capacitor 1100 shown in FIG. 4. FIG. 8 is a plan view illustrating an upper metal pattern of the MIM capacitor 1100 shown in FIG. 4. The cross-sectional′view illustrated in FIG. 4 corresponds to a merged cross-sectional view taken along lines I-I′ of FIGS. 5 to 8. In FIGS. 4 to 8, the same reference numerals denote the same elements.

Referring to FIG. 4, the MIM capacitor 1100 may include a lower metal pattern 1150, a dielectric pattern 1160 and an upper metal pattern 1170 which are sequentially stacked in a capacitor region 1111. The dielectric pattern 1160 and the upper metal pattern 1170 may extend onto a peripheral region 1112 surrounding edges of the capacitor region 1111. The MIM capacitor 1100 may be on a metal layer 1130 and a dummy insulation pattern 1140 stacked on the metal layer 1130. The metal layer 1130 may be an interconnection layer and may be on an insulation layer 1120 stacked on a substrate 1110. The insulation layer 1120 may be an interlayer insulation layer (also, referred to as an interlayer dielectric layer) or an inter-metal insulation layer (also, referred to as an inter-metal dielectric layer). In some embodiments, at least one of the lower metal pattern 1150 and the upper metal pattern 1170 may be a single metal material layer or a metal compound layer such as a tantalum nitride (TaN) layer or a titanium nitride (TiN) layer. The capacitor region 1111 may be a region in which the MIM capacitor 1100 is disposed. The peripheral region 1112 may have a certain width and may surround the capacitor region 1111. Although not shown in the drawings, only a portion of the MIM capacitor 1100 may be on the metal layer 1130, and the remaining portion of the MIM capacitor 1100 may be on the insulation layer 1120.

As illustrated in FIG. 5, the dummy insulation pattern 1140 may be disposed in both of the capacitor region 1111 and the peripheral region 1112. In FIG. 5, the capacitor region 1111 and the peripheral region 1112 may be distinguished from each other by a dotted line “A”. A plurality of contact holes 1142 may be disposed in the capacitor region 1111 to penetrate the dummy insulation pattern 1140. Each of the contact holes 1142 may expose a portion of the metal layer 1130. Although FIG. 5 illustrates an example in which each of the contact holes 1142 has a circular shape in a plan view, the present disclosure is not limited thereto. For example, each of the contact holes 1142 may have a different shape than a circular shape in a plan view. In addition, the number of the contact holes 1142 may be different. The contact holes 1142 may be spaced apart from each other by a certain distance. Further, the contact holes 1142 may be disposed so that central points of three adjacent contact holes 1142 are respectively located at three vertices of a regular triangle indicated by lines 1144. Furthermore, the dummy insulation pattern 1140 may be comprised of a single oxide type insulation layer or a plurality of insulation layers.

As illustrated in FIG. 6, the lower metal pattern 1150 may be disposed on the dummy insulation pattern 1140. The lower metal pattern 1150 may be disposed on the dummy insulation pattern 1140 throughout the capacitor region 1111 and may expose a top surface of the dummy insulation pattern 1140 in the peripheral region 1112. The lower metal pattern 1150 in the capacitor region 1111 may be on a top surface of the dummy insulation pattern 1140, side ails of the dummy insulation pattern 140 corresponding to inner walls of the contact holes 1142, and portions of the metal layer 1130 exposed by the contact holes 1142. First trenches 1152 may be defined by the lower metal pattern 1150 in the contact holes, respectively. Each of the first trenches 1152 may have a planar area that remains after subtracting a planar area of the lower metal pattern 1150 disposed on a sidewall of each contact hole 1142 from a planar area of each contact hole 1142. Since the lower metal pattern 1150 is disposed even on a top surface of the dummy insulation pattern 1140, portions of the lower metal pattern 1150 disposed in the contact holes 1142 may be connected to each other to constitute a single unified body throughout the capacitor region 1111.

As illustrated in FIG. 7, the dielectric pattern 1160 may be disposed on an entire portion of the lower metal pattern 1150, disposed throughout the capacitor region 1111, and on a portion of the dummy insulation pattern 1140 disposed in the peripheral region 1112. Further, the dielectric pattern 1160 may be a high-k dielectric layer such as a silicon nitride (SiN) layer, an aluminum oxide (Al₂O₃) layer, a tantalum pentoxide (Ta₂O₅) layer, a zirconium oxide (ZrO₂) layer or a hafnium oxide (HfO₂) layer. Alternatively, the dielectric pattern 1160 may be a high-k dielectric layer comprised of a composite layer such as a ZrO₂/Al₂O₃/ZrO₂ layer. Second trenches 1162 may be defined by the dielectric pattern 1160 in the contact holes, respectively. Each of the second trenches 1162 may have a planar area that remains after subtracting a planar area of the dielectric pattern 1160 disposed on a sidewall of each first trench 1152 from a planar area of each first trench 1152. The dielectric pattern 1160 may occupy an entire portion of the capacitor region 1111 and a portion of the peripheral region 1112. A step between a top surface of the lower metal pattern 1150 and a top surface of the dummy insulation pattern 1140 may exist in a boundary region between the capacitor region 1111 and the peripheral region 1112. Thus, a top surface of the dielectric pattern 1160 may also have a step that is spaced apart from a boundary between the capacitor region 1111 and the peripheral region 1112 toward the peripheral region 1112 by a distance D1. An edge of the dielectric pattern 1160 may be spaced apart from boundary between the capacitor region 1111 and the peripheral region 1112 toward the peripheral region 1112 by a distance D3. The distance D3 from the boundary between the capacitor region 1111 and the peripheral region 1112 to an edge of the dielectric pattern 1160 may be greater than the distance D1 from the boundary between the capacitor region 1111 and the peripheral region 1112 to a position where the step of the top surface of the dielectric pattern 1160 exists in the peripheral region 1112.

As illustrated in FIG. 8, the upper metal pattern 1170 may be disposed on the dielectric pattern 1160 in the capacitor region 1111 and the peripheral region 1112. The upper metal pattern 1170 in the capacitor region 1111 may completely fill all of the second trenches 1162. The upper metal pattern 1170 may occupy an entire portion of the capacitor region 1111 and a portion of the peripheral region 1112. Edges of the upper metal pattern 1170 may be vertically aligned with edges of the dielectric pattern 1160 in the peripheral region 1112. In such a case, a distance D4 from the boundary between the capacitor region 1111 and the peripheral region 1112 to the edges of upper metal pattern 1170 may be equal to the distance D3 from the boundary between the capacitor region 1111 and the peripheral region 1112 to the edges of the dielectric pattern 1160. A top surface of the upper metal pattern 1170 may have a step that is spaced apart from the boundary between the capacitor region 1111 and the peripheral region 1112 toward the peripheral region 1112 by the distance D2. The distance D2 may be greater than the distance D1 from the boundary between the capacitor region 1111 and the peripheral region 1112 to a position where the step of the top surface of the dielectric pattern 1160 exists in the peripheral region 1112. The distance D4 from the boundary between the capacitor region 1111 and the peripheral region 1112 to the edges of upper metal pattern 1170 may be greater than the distance D2 from the boundary between the capacitor region 1111 and the peripheral region 1112 to a position where the step of the top surface of the upper metal pattern 1170 exists in the peripheral region 1112.

A capacitance value of the MIM capacitor 1100 may be directly proportional to an overlap area between the lower metal pattern 1150 and the upper metal pattern 1170. In the MIM capacitor 1100, the lower metal pattern 1150 and the upper metal pattern 1170 may vertically overlap throughout the capacitor region 1111. Thus, if a dielectric constant and a thickness of the dielectric pattern 1160 between the lower metal pattern 1150 and the upper metal pattern 1170 are uniform throughout the capacitor region 1111, the MIM capacitor 1100 may exhibit a maximum capacitance value in the capacitor region 1111. Particularly, the MIM capacitor 1100 may include the lower metal pattern 1150 which is disposed even on the top surface of the dummy insulation pattern 1140 having the contact holes 1142. Accordingly, the MIM capacitor 1100 may be disposed throughout the capacitor region 1111. That is, an entire bottom surface and an entire top surface of the dielectric pattern 1160 may respectively contact the lower metal pattern 1150 and the upper metal pattern 1170 throughout the capacitor region 1111. Thus, a total area of the capacitor region 1111 may fully participate in calculation of the capacitance value of the MIM capacitor 1100. Unlike a general MIM capacitor having a plurality of lower metal patterns which are divided by a node separation process, in the MIM capacitor 1100, the lower metal pattern 1150 may be disposed even on the top surface of the dummy insulation pattern 1140 as well as sidewalls of the dummy insulation pattern 1140 sidewalls of the contact holes 1142). As a result, a portion of the MIM capacitor 1100 may be provided even on the top surface of the dummy insulation pattern 1140 to increase a capacitance of the MIM capacitor 1100.

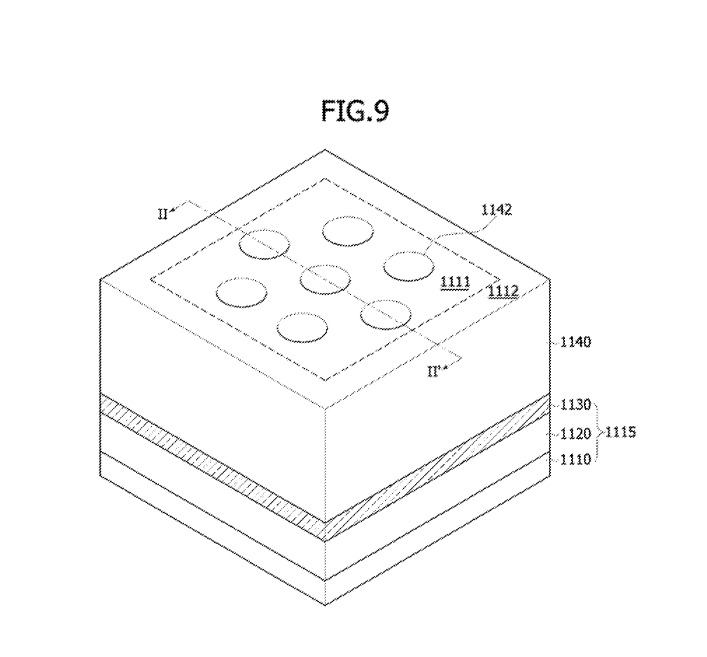

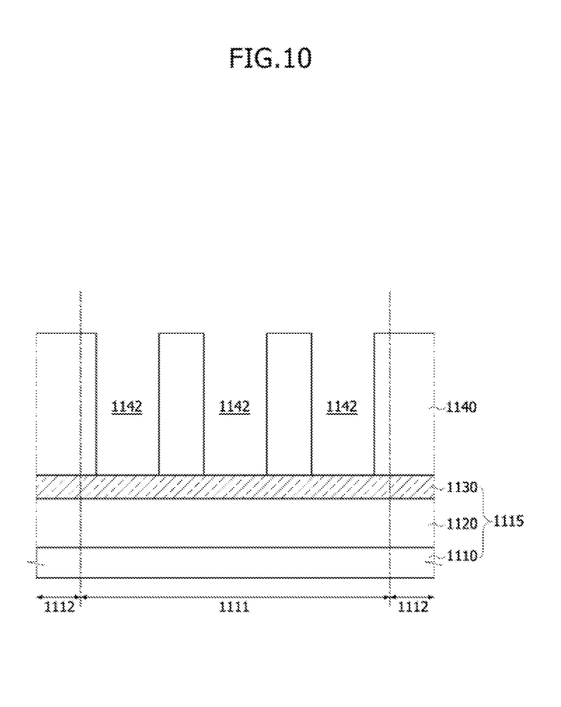

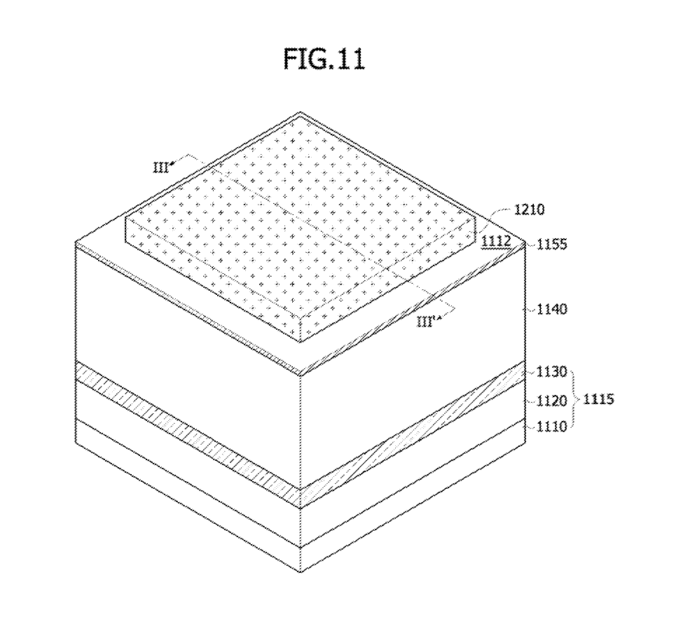

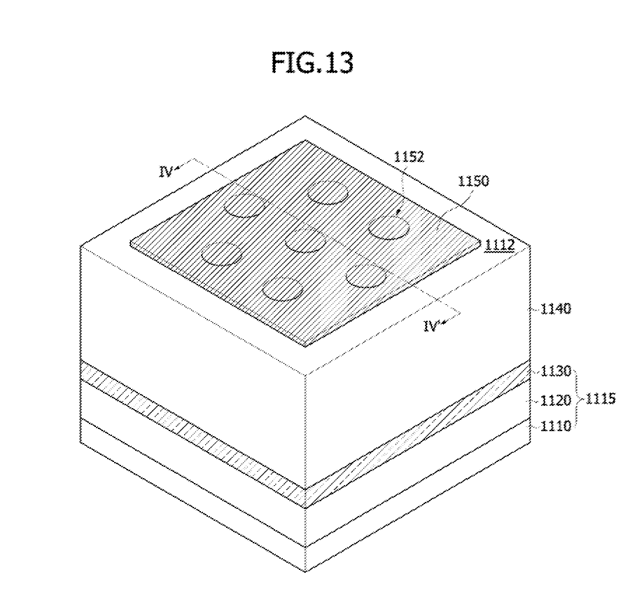

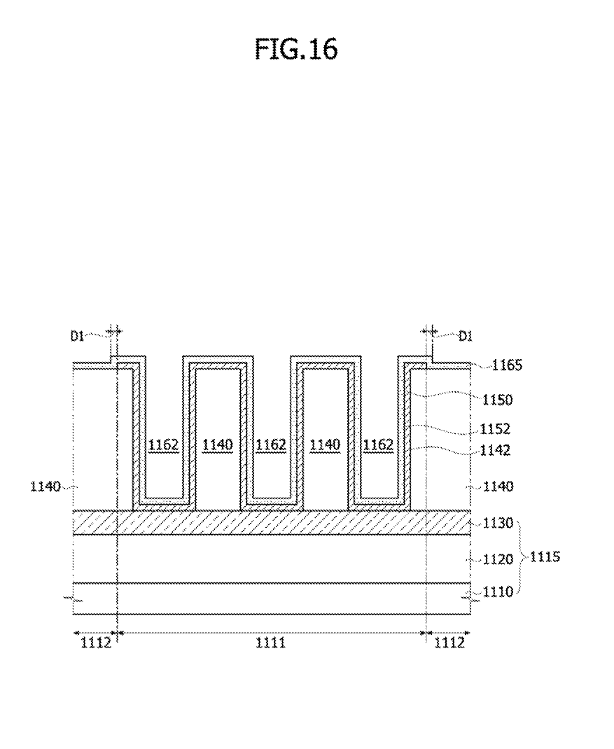

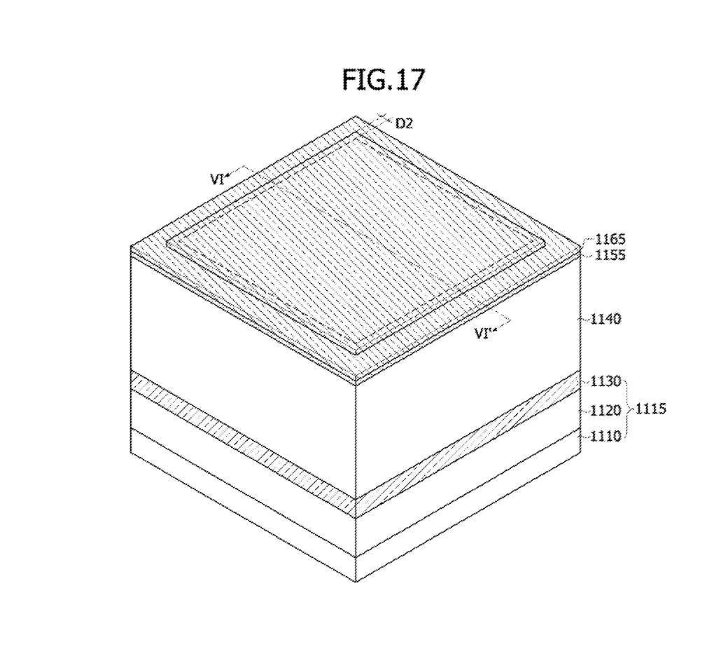

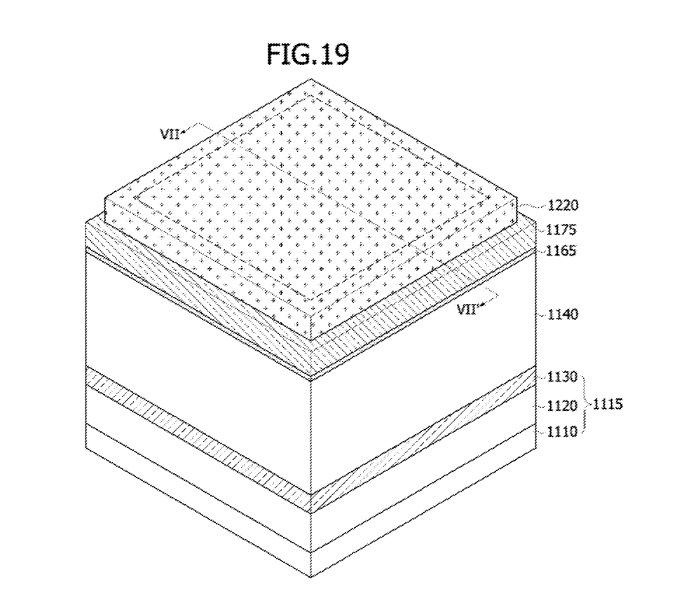

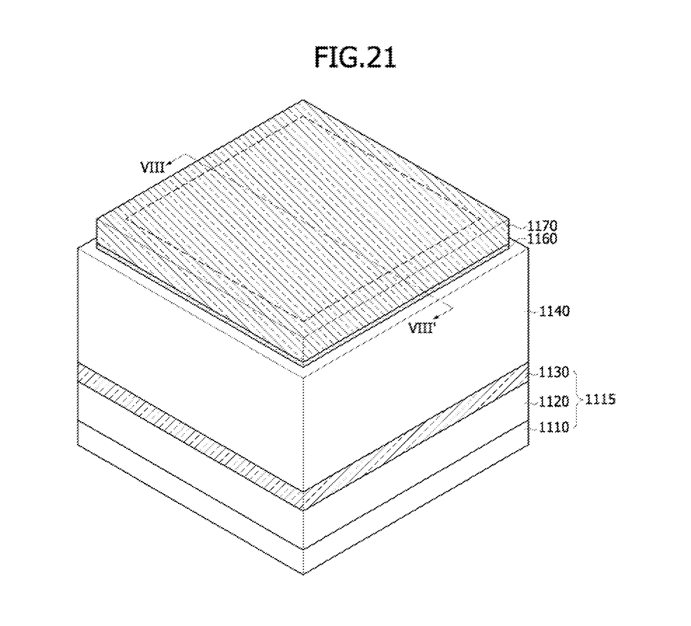

FIGS. 6 to 19 are perspective views and cross-sectional views illustrating a method of fabricating an MIM capacitor according to an embodiment. FIGS. 10, 12, 14, 16, 18, 20 and 22 are cross-sectional views taken along a line II-II′ of FIG. 9, a line III-III′ of FIG. 11, a line IV-IV′ of FIG. 13, a line V-V′ of FIG. 15, a line VI-VI′ of FIG. 17, a line VII-VII′ of FIG. 19 and a line VIII-VIII′ of FIG. 21, respectively. In FIGS. 9 to 22, the same reference numerals denote the same elements.

Referring to FIGS. 9 and 10, a dummy insulation pattern 1140 may be formed on an underlying structure 1115. Further, the underlying structure 1115 may be formed to include a substrate 1110, an insulation layer 1120 disposed on the substrate 1110, and a metal layer 1130 disposed on the insulation layer 1120. In such a case, the metal layer 1130 may be a portion of an interconnection line. A dummy insulation pattern 1140 may be formed on the metal layer 1130. The dummy insulation pattern 1140 may be formed in an entire portion of a capacitor region 1111 and in an entire portion of a peripheral region 1112 surrounding the capacitor region 1111. As illustrated in FIGS. 9 and 10, the capacitor region 1111 and the peripheral region 1112 may be distinguished from each other by a dotted line. The dummy insulation pattern 1140 may be formed to have a plurality of contact holes 1142 that expose portions of the metal layer 1130. Specifically, a dummy insulation layer may be formed on an entire surface of the metal layer 1130, and a first mask pattern may be formed on the dummy insulation layer to expose portions of the dummy insulation layer. Furthermore, the first mask pattern may be formed of a photoresist layer. The dummy insulation layer may be etched using the first mask pattern as an etch mask, thereby forming the contact holes 1142 and the dummy insulation pattern 1140. After forming the dummy insulation pattern 1140, the first mask pattern may be removed. Further, the dummy insulation pattern 1140 may be formed of a single oxide type insulation layer or a plurality of insulation layers.

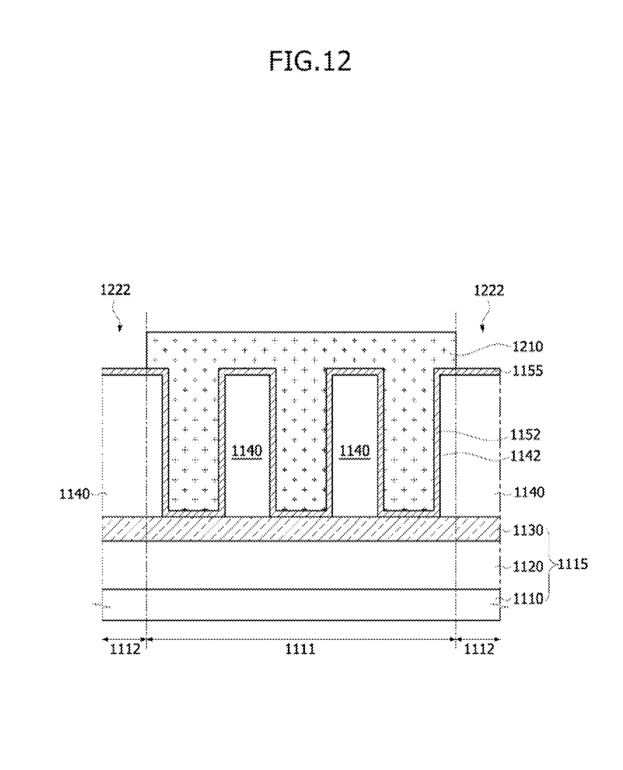

Referring to FIGS. 11 and 12, a lower metal layer 1155 may be formed on the dummy insulation pattern 1140 and in the contact holes 1142. Accordingly, the lower metal layer 1155 may be formed on a top surface of the dummy insulation pattern 1140 through the capacitor region 1111 and the peripheral region 1112. In addition, the lower metal layer 1155 may be formed even on sidewalls of the dummy insulation pattern 1140 exposed by the contact holes 1142 and portions of the metal layer 1130 exposed by the contact holes 1142. The lower metal layer 1155 may provide first trenches 1152 which are located in the contact holes 1142, respectively. Further, the lower metal layer 1155 may be formed of a single metal material layer or a metal compound layer such as a tantalum nitride (TaN) layer or a titanium nitride (TiN) layer. After forming the lower metal layer 1155, a first mask pattern 1210 may be formed on the lower metal layer 1155. Furthermore, the first mask pattern 1210 may be formed of a photoresist layer. The first mask pattern 1210 may be formed to fill the first trenches 1152 and to cover the lower metal layer 1155 in the capacitor region 1111. Moreover, the first mask pattern 1210 may be formed to have an opening 1222 that exposes the lower metal layer 1155 in the peripheral region 1112.

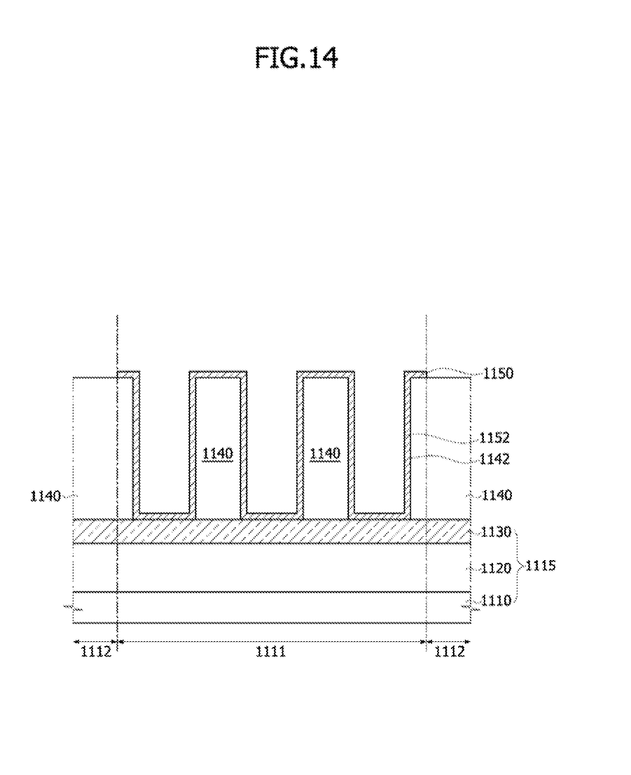

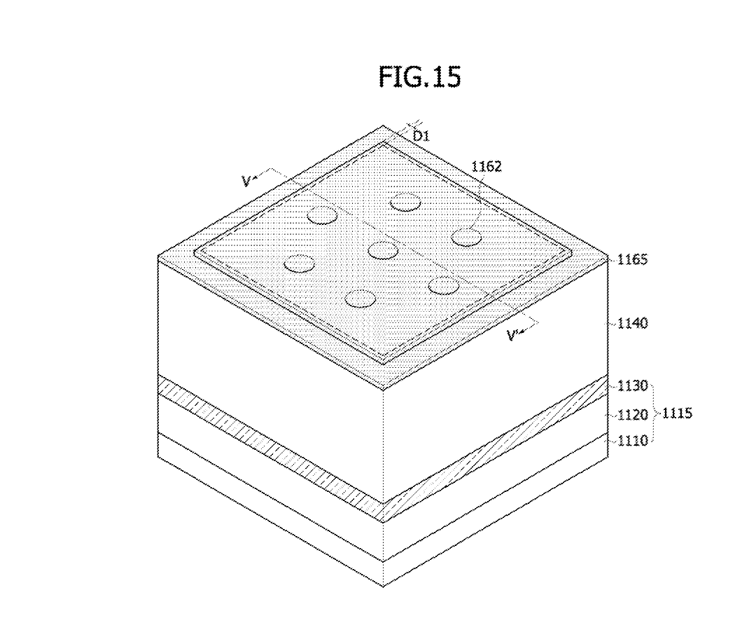

Referring to FIGS. 13 and 14, the lower metal layer (1155 of FIGS. 11 and 12) may be etched using the first mask pattern (1210 of FIGS. 11 and 12) as an etch mask, thereby exposing the lower metal layer 1155 in the peripheral region 1112. As a result, a lower metal pattern 1150 may be formed in the capacitor region 1111. That is, the lower metal pattern 1150 may be formed only in the capacitor region 1111. Since the lower metal layer 1155 in the capacitor region 1111 is covered and protected by the first mask pattern (1210 of FIGS. 11 and 12) during the etch process for forming the lower metal pattern 1150, the lower metal pattern 1150 may remain on a top surface of the dummy insulation pattern 1140 in the capacitor region 1111 without node separation. Thus, the lower metal pattern 1150 may b have a single pattern. After the lower metal pattern 1150 is formed, the first mask pattern 1210 may be removed.

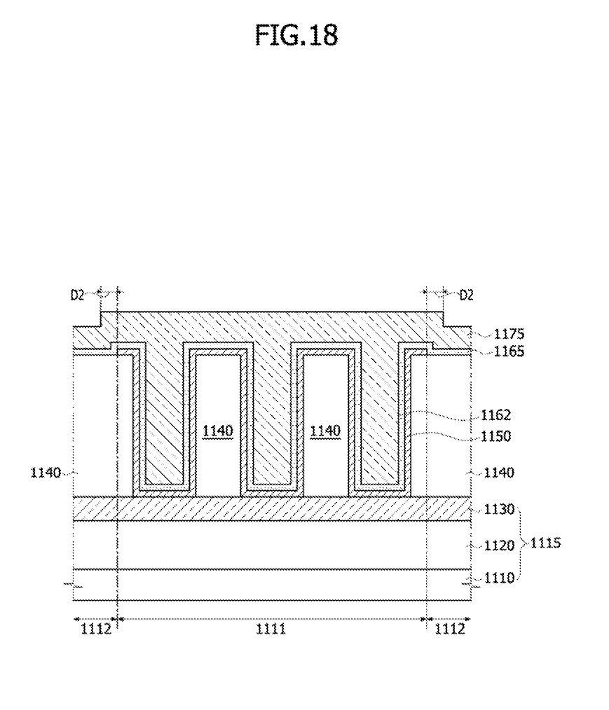

Referring to FIGS. 15 and 18, a dielectric layer 1165 may be formed on the lower metal pattern 1150 located in the capacitor region 1111 and on the dummy insulation pattern 1140 located in the peripheral region 1112. The dielectric layer 1165 may provide second trenches 1162 which are located in the first trenches 1152, respectively. Further, the dielectric layer 1165 may be formed of a high-k dielectric layer such as a silicon nitride (SiN) layer, an aluminum oxide (Al₂O₃) layer, a tantalum pentoxide (Ta₂O₅) layer, a zirconium oxide (ZrO₂) layer or a hafnium oxide (HfO₂) layer. Alternatively, the dielectric layer 1165 may be formed of a high-k dielectric layer comprised of a composite layer such as a ZrO₂/Al₂O₃/ZrO₂ layer. Since the lower metal pattern 1150 is formed only in the capacitor region 1111, edges of the lower metal pattern 1150 may be aligned with a boundary between the capacitor region 1111 and the peripheral region 1112. Thus, after the dielectric layer 1165 is formed, a top surface of the dielectric layer 1165 may have a step that is spaced apart from the boundary between the capacitor region 1111 and the peripheral region 1112 toward the peripheral region 1112 by a distance D1 because of a step between the lower metal pattern 1150 and the dummy insulation pattern 1140 generated at the boundary between the capacitor region 1111 and the peripheral region 1112.

Referring to FIGS. 17 and 18, an upper metal layer 1175 may be formed on the dielectric layer 1165. The upper metal layer 1175 may be formed to cover an entire top surface of the dielectric layer 1165 throughout the capacitor region 1111 and the peripheral region 1112. In addition, the upper metal layer 1175 may be formed to fill the second trenches 1162 which are provided by the dielectric layer 1165. Further, the upper metal layer 1175 may be formed of a single metal material layer or a metal compound layer such as a tantalum nitride (TaN) layer or a titanium nitride (TiN) layer. After the upper metal layer 1175 is formed, a top surface of the upper metal layer 1175 may have a step that is spaced apart from the boundary between the capacitor region 1111 and the peripheral region 1112 toward the peripheral region 1112 by a distance D2 because of a step of the dielectric layer 1165 in the peripheral region 1112. The step of the upper metal layer 1175 may be formed between a position of the step of the dielectric layer 1165 and an edge of the peripheral region 1112.

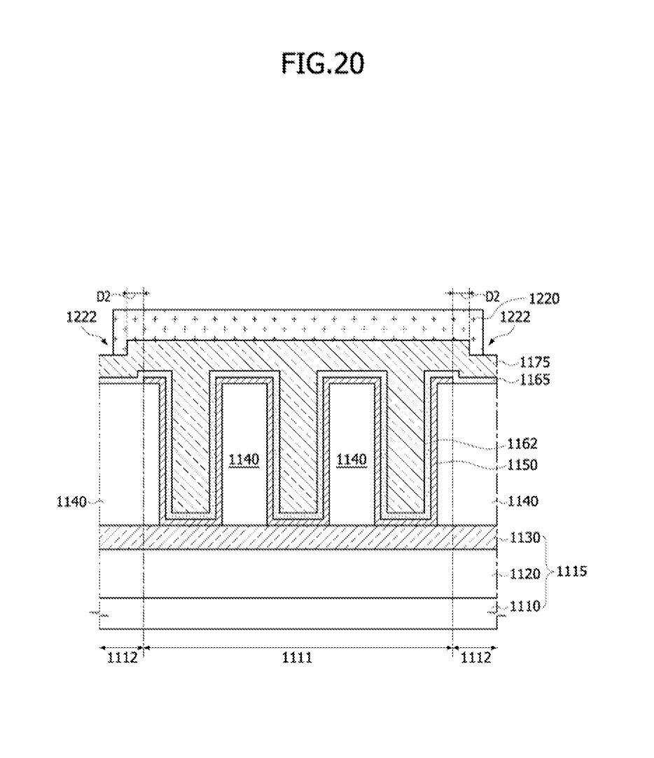

Referring to FIGS. 19 and 20, a second mask pattern 1220 may be formed on the upper metal layer 1175 after the upper metal layer 1175 is formed. Further, the second mask pattern 1220 may be formed of a photoresist layer. The second mask pattern 1220 may cover an entire portion of the upper metal layer 1175 in the capacitor region 1111 and a portion of the upper metal layer 1175 in the peripheral region 1112. That is, the second mask pattern 1220 may have an opening 1222 that exposes edges of the upper metal layer 1175 in the peripheral region 1112.

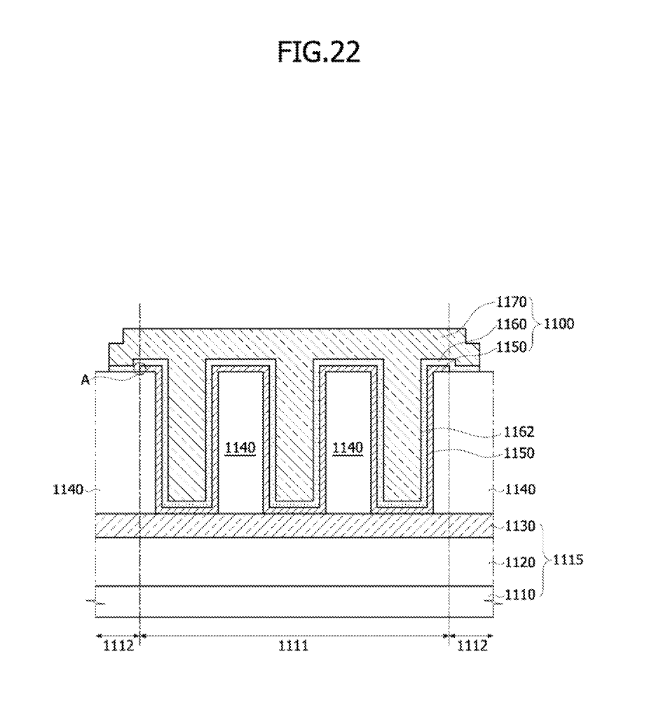

Referring to FIGS. 21 and 22, the upper metal layer (1175 of FIGS. 19 and 20) and the dielectric layer (1165 of FIGS. 19 and 20) may be sequentially etched using the second mask pattern (1220 of FIGS. 19 and 20) as an etch mask, thereby forming an upper metal pattern 1170 and a dielectric pattern 1160. Thus, the upper metal pattern 1170 may be formed in an entire portion of the capacitor region 1111 and in a portion of the peripheral region 1112. Similarly, the dielectric pattern 1160 may a so be formed in an entire portion of the capacitor region 1111 and in a portion of the peripheral region 1112. Edges of the upper metal pattern 1170 may be aligned with edges of the dielectric pattern 1160 in the peripheral region 1112. After the upper metal pattern 1170 and the dielectric pattern 1160 are formed, the second mask pattern 1220 may be removed. The upper metal pattern 1170, the dielectric pattern 1160 and the lower metal pattern 1150 may constitute an MIM capacitor 1100.

While the upper metal pattern 1170 and the dielectric pattern 1160 are formed by an etch process that employs the second mask pattern 1220 as an etch mask, edges (see a portion indicated by a character “A”) of the lower metal pattern 1150 may not be damaged by the etch process because the edges “A” of the lower metal pattern 1150 are still covered with the dielectric pattern 1160. In particular, even though the upper metal layer 1175 is over-etched to completely remove the upper metal layer 1175 exposed by the opening (1222 of FIG. 20) of the second mask pattern 1220 no damage may occur to the lower metal pattern 1150. Thus, the upper metal layer 1175 may be fully over-etched to completely remove the upper metal layer 1175 exposed by the opening (1222 of FIG. 20) of the second mask pattern 1220 even without employing any etch stop layer that is generally used to prevent the conductive bridges between the lower metal pattern 1150 and the upper metal pattern 1170 from being formed.

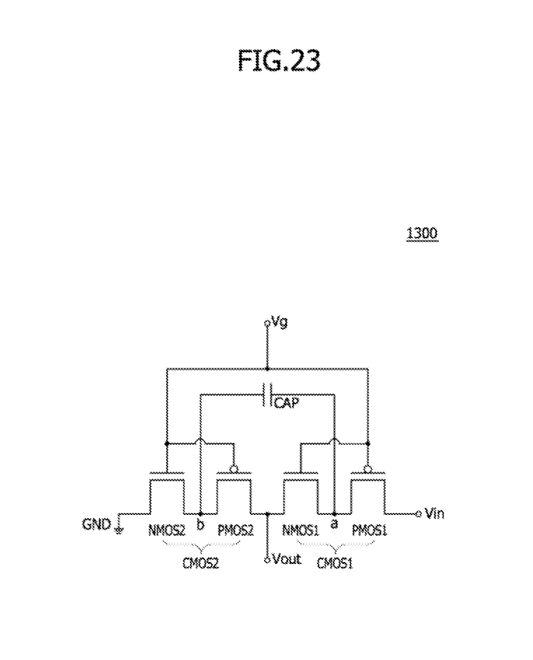

FIG. 23 is a circuit diagram illustrating a switched-capacitor converter (SCC) 1300 employing an MIM capacitor. Although FIG. 23 illustrates an example in which the MIM capacitor is employed in an SCC, the present disclosure is not limited thereto. That is, the MIM capacitor according to the embodiments may also be employed in an electronic device other than the SCC. Referring to FIG. 23, the SCC 1300 may be a DC-to-DC converter and may include a first complementary metal-oxide-semiconductor (CMOS) inverter CMOS1, a second CMOS inverter CMOS2 and a capacitor CAP. The first CMOS inverter CMOS1 may include a first N-channel MOS transistor NMOS1 and a first P-channel MOS transistor PMOS1. The second CMOS inverter CMOS2 may include a second N-channel MOS transistor NMOS2 and a second P-channel MOS transistor PMOS2. The capacitor CAP may correspond to the MIM capacitor 1100 described with reference to FIGS. 4 to 8.

Each of the first and second N-channel MOS transistors NMOS1 and NMOS2 may have a source terminal corresponding to an N-type source region and a drain terminal corresponding to an N-type drain region. Each of the first and second P-channel MOS transistors PMOS1 and PMOS2 may have a source terminal corresponding to a P-type source region and a drain terminal corresponding to a P-type drain region. The source terminal and the drain terminal of the first P-channel MOS transistor PMOS1 may be connected to an input voltage terminal Vin and the drain terminal of the first N-channel MOS transistor NMOS1, respectively. The source terminal of the first N-channel MOS transistor NMOS1 may be connected to an output voltage terminal Vout. The source terminal and the drain terminal of the second P-channel MOS transistor PMOS2 may be connected to the output voltage terminal Vout and the drain terminal of the second N-channel MOS transistor NMOS2, respectively. The source terminal of the second N-channel MOS transistor NMOS2 may be connected to a ground terminal GND. One terminal of the capacitor CAP may be connected to a connection node “a” that connects the drain terminal of the first P-channel MOS transistor PMOS1 to the drain terminal of the first N-channel MOS transistor NMOS1. The other terminal of the capacitor CAP may be connected to a connection node “b” that connects the drain terminal of the second P-channel MOS transistor PMOS2 to the drain terminal of the second N-channel MOS transistor NMOS2. Gate terminals of the first P-channel MOS transistor PMOS1 and the first N-channel MOS transistor NMOS1 as well as gate terminals of the second P-channel MOS transistor PMOS2 and the second N-channel MOS transistor NMOS2 may be commonly connected to a gate voltage input terminal Vg.

The SCC 1300 according to the present embodiment may function as a DC-to-DC converter that converts a source of direct current (DC) from one voltage level to another voltage level with two operation phases, for example, a charging phase and a discharging phase. During operation of the SCC 1300, a clock signal may be inputted to the SCC 1300 through the gate voltage input terminal Vg. Specifically, in the charging phase, a gate voltage signal lower than a certain voltage level (e.g., a threshold voltage of the first and second N-channel MOS transistors NMOS1 and NMOS2) for example, a gate voltage signal having a ground voltage level may be applied to the gate voltage input terminal Vg. Accordingly, while the first and second P-channel MOS transistors PMOS1 and PMOS2 are turned on, the first and second N-channel MOS transistors NMOS1 and NMOS2 may be turned off. In such a case, a current path may be provided between the input voltage terminal Vin and the output voltage terminal Vout through the connection node “a”, the capacitor CAP and the connection node “b”, and the capacitor CAP may be charged to store a predetermined amount of electric charge therein if an input voltage signal is applied to the input voltage terminal Vin. In the discharging phase, a gate voltage signal higher than a certain voltage level (e.g., a threshold voltage of the first and second N-channel MOS transistors NMOS1 and NMOS2), for example, a gate voltage signal of 5 volts may be applied to the gate voltage input terminal Vg. Accordingly, while the first and second N-channel MOS transistors NMOS1 and NMOS2 are turned on, the first and second P-channel MOS transistors PMOS1 and PMOS2 may be turned off. In such a case, both terminals of the capacitor CAP may be connected to the ground terminal GND and the output voltage terminal Vout, respectively. Thus, the charged capacitor CAP may act as a voltage source to output a voltage having a different level from the input voltage signal through the output voltage terminal Vout.

A conversion ratio of the output voltage to the input voltage may change according to a capacitance of the capacitor CAP. If the capacitance of the capacitor CAP increases, the conversion ratio of the output voltage to the input voltage may also increase. Thus, in order to obtain a high conversion ratio of the SCC 1300, it may be necessary to increase the capacitance of the capacitor CAP. As described with reference to FIGS. 4 to 8, the lower metal pattern 1150 of the MIM capacitor 1100 may be disposed even on the top surface of the dummy insulation pattern 1140 as well as the sidewalls of the contact holes 1142, unlike a general MIM capacitor having a lower metal pattern formed with a node separation process. Thus, a capacitance of the MIM capacitor 1100 may increase compared with the general MIM capacitor. Therefore, if the MIM capacitor 1100 is employed as the capacitor CAP of the SCC 1300, a voltage conversion ratio of the SCC 1300 may increase.

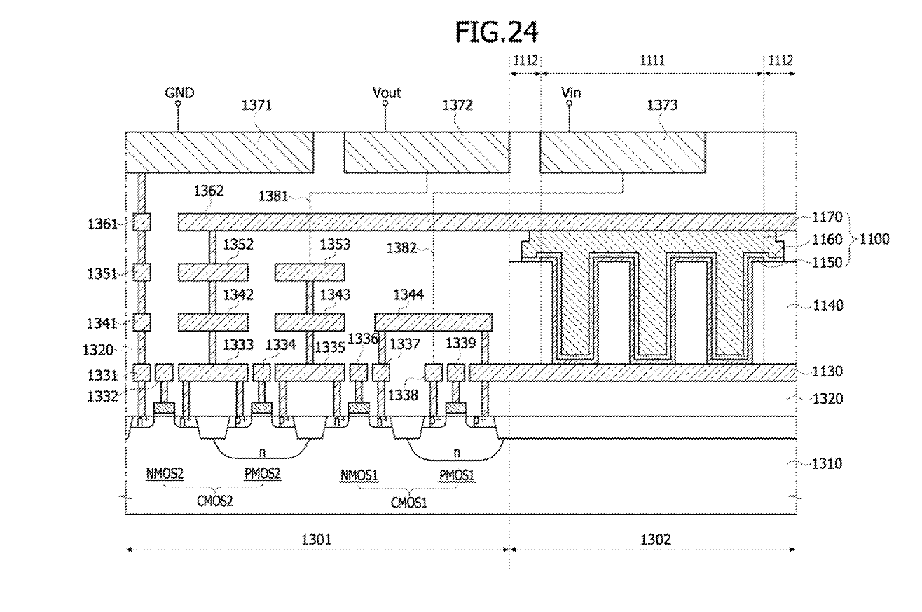

FIG. 24 is a cross-sectional view illustrating an SCC device corresponding to the SCC 1300 shown in FIG. 23. Referring to FIG. 24, the SCC device may include a first region 1301 in which switching elements are disposed and a second region 1302 in which a capacitor is disposed, and the first and second regions 1301 and 1302 may be adjacent to each other and may be defined in two adjacent regions of a substrate 1310 in a horizontal direction. Specifically, the substrate 1310 may have the first and second regions 1301 and 1302 that are distinguished from each other in a horizontal direction. Further, the substrate 1310 may be a P-type substrate. A first CMOS inverter CMOS1 and a second CMOS inverter CMOS2 functioning as switching elements may be disposed in the first region 1301. The first CMOS inverter CMOS1 may include a first P-channel MOS transistor PMOS1 and a first N-channel MOS transistor NMOS1. The second CMOS inverter CMOS2 may include a second P-channel MOS transistor PMOS2 and a second N-channel MOS transistor NMOS2. The second region 1302 may include a capacitor region 1111 in which a capacitor 1100 is disposed and a peripheral region 1112 surrounding the capacitor region 1111.

A plurality of junction regions may be disposed in upper regions of the substrate 1310 in the first region 1301. Channel regions may be defined between the junction regions, and a gate insulation layer and a gate electrode may be sequentially stacked on each of the channel regions. Each of the first and second P-channel MOS transistors PMOS1 and PMOS2 may have P-type junction regions acting as source and drain regions. The P-type junction regions of each of the first and second P-channel MOS transistors PMOS1 and PMOS2 may be surrounded by an N-type well region.

Each of the first and second N-channel MOS transistors NMOS1 and NMOS2 may have N-type junction regions acting as source and drain regions. The first and second P-channel MOS transistors PMOS1 and PMOS2 and the first and second N-channel MOS transistors NMOS1 and NMOS2 may be isolated from each other by a trench isolation layer that is disposed in an upper region of the substrate 1310. An insulation layer 1320 may be disposed on the substrate 1310 in the first region 1301. Although the insulation layer 1320 is not divided into a plurality of layers in FIG. 24, the insulation layer 1320 may have a multi-layered structure. A multi-level interconnection structure may be disposed in the insulation layer 1320. Further, first interconnection patterns 1130 and 1331 to 1339 may be disposed at a lowermost level, and second interconnection patterns 1341 to 1344, third interconnection patterns 1351 to 1353, fourth interconnection patterns 1361 to 1362, and fifth interconnection patterns 1371 to 1373 may be vertically stacked on the first interconnection patterns 1130 and 1331 to 1339.

The first interconnection patterns 1331 may be electrically connected to the source region of the second N-channel MOS transistor NMOS2 through a via plug. The first interconnection patterns 1332, 1334, 1336 and 1339 may be electrically connected to the gate electrode of the second N-channel MOS transistor NMOS2, the gate electrode of the second P-channel MOS transistor PMOS2, the gate electrode of the first N-channel MOS transistor NMOS1, and the gate electrode of the first P-channel MOS transistor PMOS1 through via plugs respectively. Although not illustrated in FIG. 24, the first interconnection patterns 1332, 1334, 1336 and 1339 may be electrically connected to a gate voltage input terminal (corresponding to the gate voltage input terminal Vg of FIG. 23). The first interconnection pattern 1333 may be electrically connected to the drain regions of the second N-channel MOS transistor NMOS2 and the second P-channel MOS transistor PMOS2 through via plugs. The first interconnection pattern 1335 may be electrically connected to the source regions of the second P-channel MOS transistor PMOS2 and the first N-channel MOS transistor NMOS1 through via plugs. The first interconnection pattern 1337 may be electrically connected to the drain region of the first N-channel MOS transistor NMOS1 through a via plug. The first interconnection patterns 1338 and 1130 may be electrically connected to the source region and the drain region of the first P-channel MOS transistor PMOS1 through via plugs, respectively.

The first interconnection pattern 1331 may be electrically connected to the fifth interconnection pattern 1371, which is located at an uppermost level, through the second, third and fourth interconnection patterns 1341, 1351 and 1361. The first, second, third, fourth and fifth interconnection patterns 1331, 1341, 1351, 1361 and 1371 may be electrically connected to each other through via plugs therebetween. The fifth interconnection pattern 1371 may be electrically connected to a ground pad GND. Thus, the source region of the second N-channel MOS transistor NMOS2 may be electrically connected to the ground pad GND. The first interconnection pattern 1333 may be electrically connected to the fourth interconnection pattern 1362 through the second and third interconnection patterns 1342 and 1352. The first, second, third and fourth interconnection patterns 1333, 1342, 1352 and 1362 may be electrically connected to each other through via plugs therebetween. The fourth interconnection pattern 1362 may be electrically connected to an upper metal pattern 1170 of the capacitor 1100 disposed in the second region 1302.

The first interconnection pattern 1335 may be electrically connected to the fifth interconnection pattern 1372 through the second and third interconnection patterns 1343 and 1353. The first, second, third and fifth interconnection patterns 1335, 1343, 1353 and 1372 may be electrically connected to each other through via plugs therebetween. An interconnection structure between the third interconnection pattern 1353 and the fifth interconnection pattern 1372 is not illustrated in FIG. 24. However, as indicated by a dotted line 1381 in FIG. 24, the third interconnection pattern 1353 and the fifth interconnection pattern 1372 may be electrically connected to each other through any one of various interconnection structures, for example, through a via plug and another fourth interconnection pattern (not shown). The fifth interconnection pattern 1372 may be electrically connected to an output voltage pad Vout. Thus, the source regions of the second P-channel MOS transistor PMOS2 and the first N-channel MOS transistor NMOS1 may be electrically connected to the output voltage pad Vout.

The first interconnection patterns 1337 and 1130 may be electrically connected to the second interconnection pattern 1344. The first interconnection patterns 1337 and 1130 and the second interconnection pattern 1344 may be electrically connected to each other through via plugs therebetween. The first interconnection pattern 1130 may be electrically connected to a lower metal pattern 1150 of the capacitor 1100 disposed in the second region 1302. Accordingly, the drain regions of the first N-channel MOS transistor NMOS1 and the first P-channel MOS transistor PMOS1 may be electrically connected to the lower metal pattern 1150 of the capacitor 1100. The first interconnection pattern 1338 may be electrically connected to the fifth interconnection pattern 1373. An interconnection structure between the first interconnection pattern 1338 and the fifth interconnection pattern 1373 is not illustrated in FIG. 24. However, as indicated by a dotted line 1382 in FIG. 24, the first interconnection pattern 1338 and the fifth interconnection pattern 1373 may be electrically connected to each other through any one of various interconnection structures, for example, through a via plug and other third and fourth interconnection patterns (not shown). The fifth interconnection pattern 1373 may be electrically connected to an input voltage pad Vin. Thus, the source region of the first P-channel MOS transistor PMOS1 may be electrically connected to the input voltage pad Vin.

The trench isolation layer may also be disposed in an upper region of the substrate 1310 in the second region 1302. Although not shown in FIG. 24, active elements such as MOS transistors and/or passive elements such as resistors may be disposed on the substrate 1310 in the second region 1302. If the active elements such as MOS transistors are disposed in the second region 1302, junction regions of the MOS transistors may be disposed in the substrate 1310 in the second region 1302. The insulation layer 1320 may also be disposed on the substrate 1310 in the second region 1302, and the first interconnection pattern 1130 may be disposed on the insulation layer 1320. The first interconnection pattern 1130 may be the same layer as the meta layer 1130 of the MIM capacitor 1100 described with reference to FIGS. 4 to 8. A dummy insulation pattern 1140 having a plurality of contact holes may be disposed on the first interconnection pattern 1130. The dummy insulation pattern 1140 may correspond to a portion of the insulation layer 1320. In such a case, the dummy insulation pattern 1140 may be formed by depositing the insulation layer 1320 in the first and second regions 1301 and 1302 and by patterning the insulation layer 1320 in the second region 1302 with a mask pattern to form the contact holes. The lower metal pattern 1150 may be disposed on the dummy insulation pattern 1140 and in the contact holes penetrating the dummy insulation pattern 1140. A dielectric pattern 1160 and the upper metal pattern 1170 may be sequentially stacked on the lower metal pattern 1150. The fourth interconnection pattern 1362 may be disposed on the upper metal pattern 1170. The lower metal pattern 1150, the dielectric pattern 1160 and the upper metal pattern 1170 may constitute the MIM capacitor 1100. As described with reference to FIGS. 4 to 8, the lower metal pattern 1150 of the MIM capacitor 1100 may be disposed even on the top surface of the dummy insulation pattern 1140 as well as the sidewalls of the contact holes, unlike a general MIM capacitor having a lower metal pattern formed with a node separation process. Thus, a capacitance of the MIM capacitor 1100 may increase compared with the general MIM capacitor, in a limited area.

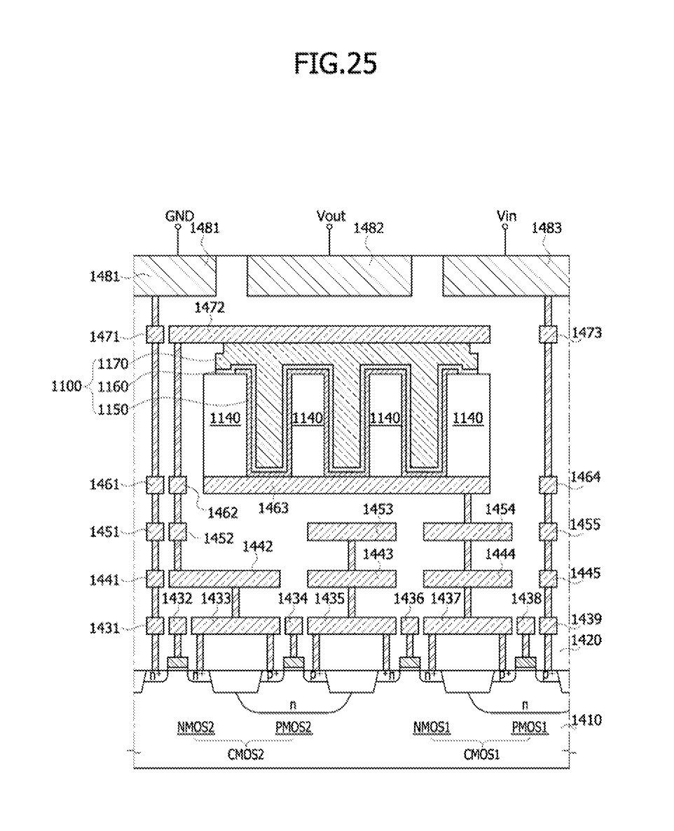

FIG. 25 is a cross-sectional view illustrating another SCC device corresponding to the SCC 1300 shown in FIG. 23. Referring to FIG. 25, the SCC device may include a first region in which switching elements are disposed and a second region in which a capacitor 1100 is disposed, and the first and second regions may vertically overlap with each other on a substrate 1410. Specifically, a first CMOS inverter CMOS1 and a second CMOS inverter CMOS2 functioning as switching elements may be disposed on the substrate 1410 having P-type conductivity. The first CMOS inverter CMOS1 may include a first P-channel MOS transistor PMOS1 and a first N-channel MOS transistor NMOS1. The second CMOS inverter CMOS2 may include a second P-channel MOS transistor PMOS2 and a second N-channel MOS transistor NMOS2.

A plurality of junction regions may be disposed in upper regions of the substrate 1410. Channel regions may be defined between the junction regions, and a gate insulation layer and a gate electrode may be sequentially stacked on each of the channel regions. Each of the first and second P-channel MOS transistors PMOS1 and PMOS2 may have P-type junction regions acting as source and drain regions. The P-type junction regions of each of the first and second P-channel MOS transistors PMOS1 and PMOS2 may be surrounded by an N-type well region. Each of the first and second N-channel MOS transistors NMOS1 and NMOS2 may have N-type junction regions acting as source and drain regions. The first and second P-channel MOS transistors PMOS1 and PMOS2 and the first and second N-channel MOS transistors NMOS1 and NMOS2 may be isolated from each other by a trench isolation layer that is disposed in an upper region of the substrate 1410. An insulation layer 1420 may be disposed on the substrate 1410. Although the insulation layer 1420 is not divided into a plurality of layers in FIG. 25, the insulation layer 1420 may have a multi-layered structure. A multi-level interconnection structure may be disposed in the insulation layer 1420. First interconnection patterns 1431 to 1439 may be disposed at a lowermost level, and second interconnection patterns 1441 to 1445, third interconnection patterns 1451 to 1455, fourth interconnection patterns 1461 to 1464, fifth interconnection patterns 1471 to 1473 and sixth interconnection patterns 1481 to 1483 may be vertically stacked on the first interconnection patterns 1431 to 1439.

The first interconnection patterns 1431 may be electrically connected to the source region of the second N-channel MOS transistor NMOS2 through a via plug. The first interconnection patterns 1432, 1434, 1436 and 1438 may be electrically connected to the gate electrode of the second N-channel MOS transistor NMOS2, the gate electrode of the second P-channel MOS transistor PMOS2, the gate electrode of the first N-channel MOS transistor NMOS1, and the gate electrode of the first P-channel MOS transistor PMOS1 through via plugs, respectively. Although not illustrated in FIG. 25, the first interconnection patterns 1432, 1434, 1436 and 1438 may be electrically connected to a gate voltage input terminal (corresponding to the gate voltage input terminal Vg of FIG. 23). The first interconnection pattern 1433 may be electrically connected to the drain regions of the second N-channel MOS transistor NMOS2 and the second P-channel MOS transistor PMOS2 through via plugs. The first interconnection pattern 1435 may be electrically connected to the source regions of the second P-channel MOS transistor PMOS2 and the first N-channel MOS transistor NMOS1 through via plugs. The first interconnection pattern 1437 may be electrically connected to the drain regions of the first N-channel MOS transistor NMOS1, and the first P-channel MOS transistor PMOS1 through via plugs. The first interconnection pattern 1439 may be electrically connected to the source region of the first P-channel MOS transistor PMOS1 through a via plug.

The first interconnection pattern 1431 may be electrically connected to the sixth interconnection pattern 1481, which is located at an uppermost level, through the second, third, fourth and fifth interconnection patterns 1441, 1451, 1461 and 1471. The first, second, third, fourth, fifth and sixth interconnection patterns 1431, 1441, 1451, 1461, 1471 and 1481 may be electrically connected to each other through via plugs therebetween. The sixth interconnection pattern 1481 may be electrically connected to a ground pad GND. Thus, the source region of the second N-channel MOS transistor NMOS2 may be electrically connected to the ground pad GND. The first interconnection pattern 1433 may be electrically connected to the fifth interconnection pattern 1472 through the second, third and fourth interconnection patterns 1442, 1452 and 1462. The first, second, third, fourth and fifth interconnection patterns 1433, 1442, 1452, 1462 and 1472 may be electrically connected to each other through via plugs therebetween. The fifth interconnection pattern 1472 may be electrically connected to an upper metal pattern 1170 of the capacitor 1100.

The first interconnection pattern 1435 may be electrically connected to the third interconnection pattern 1453 through the second pattern 1443. The first, second and third interconnection patterns 1435, 1443 and 1453 may be electrically connected to each other through via plugs therebetween. An interconnection structure between the third interconnection pattern 1453 and the sixth interconnection pattern 1482 is not illustrated in FIG. 25. However, the third interconnection pattern 1453 and the sixth interconnection pattern 1482 may be electrically connected to each other through any one of various interconnection structures. The sixth interconnection pattern 1482 may be electrically connected to an output voltage pad Vout. Thus, the source regions of the second P-channel MOS transistor PMOS2 and the first N-channel MOS transistor NMOS1 may be electrically connected to the output voltage pad Vout.

The first interconnection pattern 1437 may be electrically connected to the fourth interconnection pattern 1463 through the second and third interconnection patterns 1443 and 1453. The first, second, third and fourth interconnection patterns 1437, 1444, 1454 and 1463 may be electrically connected to each other through via plugs therebetween. The fourth interconnection pattern 1463 may be electrically connected to a lower metal pattern 1150 of the capacitor 1100. Accordingly, the drain regions of the first N-channel MOS transistor NMOS1 and the first r-channel MOS transistor PMOS1 may be electrically connected to the lower metal pattern 1150 of the capacitor 1100. The first interconnection pattern 1439 may be electrically connected to the sixth interconnection pattern 1483, which is located at the uppermost level, through the second, third, fourth and fifth interconnection patterns 1445, 1455, 1464 and 1473. The first, second, third, fourth, fifth and sixth interconnection patterns 1439, 1445, 1455, 1464, 1473 and 1483 may be electrically connected to each other through via plugs therebetween. The sixth interconnection pattern 1483 may be electrically connected to an input voltage pad Vin. Thus, the source region of the first P-channel MOS transistor PMOS1 may be electrically connected to the input voltage pad Vin.

The capacitor 1100 may be disposed on the fourth interconnection pattern 1463 and in the insulation layer 1420. The fourth interconnection pattern 1463 may be the same layer as the metal layer 1130 of the MIM capacitor 1100 described with reference to FIGS. 4 to 8. A dummy insulation pattern 1140 having a plurality of contact holes may be disposed on the fourth interconnection pattern 1463. The dummy insulation pattern 1140 may correspond to a portion of the insulation layer 1420. The lower metal pattern 1150 may be disposed on the dummy insulation pattern 1140 and in the contact holes penetrating the dummy insulation pattern 1140. A dielectric pattern 1160 and the upper metal pattern 1170 may be sequentially stacked on the lower metal pattern 1150. The fifth interconnection pattern 1472 may be disposed on the upper metal pattern 1170. The lower metal pattern 1150, the dielectric pattern 1160 and the upper metal pattern 1170 may constitute the MIM capacitor 1100. As described with reference to FIGS. 4 to 8, the lower metal pattern 1150 of the MIM capacitor 1100 may be disposed even on the top surface of the dummy insulation pattern 1140 as well as the sidewalls of the contact holes, unlike a general MIM capacitor having a lower metal pattern formed with a node separation process. Thus, a capacitance of the MIM capacitor 1100 may increase as compared with the general MIM capacitor, in a limited area.

The embodiments of the present disclosure have been disclosed above for illustrative purposes. Those of ordinary skill in the art will appreciate that various modifications, additions, and substitutions are possible, without departing from the scope and spirit of the present disclosure as disclosed in the accompanying claims.

What is claimed is:

1. A metal-insulator-metal (MIM) capacitor comprising:
an insulation pattern on an underlying structure having a capacitor region and a peripheral region surrounding the capacitor region, the insulation pattern having a plurality contact holes that expose portions of the underlying structure in the capacitor region;
a lower metal pattern in the capacitor region to cover a top surface of the insulation pattern, sidewalls of the insulation pattern corresponding to sidewalks of the contact holes, and the portions of the underlying structure exposed by the contact holes;
a dielectric pattern that covers the lower metal pattern in the capacitor region and a top surface of the insulation pattern in the peripheral region; and
an upper metal pattern on the dielectric pattern in the capacitor region and the peripheral region.

2. The MIM capacitor of claim 1, wherein the lower metal pattern is not on a top surface of the insulation pattern in the peripheral region.

3. The MIM capacitor of claim 1, wherein the dielectric pattern extends from a boundary between a capacitor region and the peripheral region and into the peripheral region by a first predetermined distance.

4. The MIM capacitor of claim 1, wherein the upper metal pattern extends from a boundary between the capacitor region and the peripheral region and into the peripheral region by a second predetermined distance.

5. The MIM capacitor of claim 1, wherein the underlying structure includes a metal interconnection pattern.

6. The MIM capacitor of claim 2, wherein the lower metal pattern is in direct contact with a portion of the metal interconnection pattern.

7. The MIM capacitor of claim 1, wherein central points of three adjacent contact holes are located at three vertices of a regular triangle.

8. The MIM capacitor of claim 1, wherein a top surface of the dielectric pattern has a step that is spaced apart from a boundary between the capacitor region and the peripheral region and into the peripheral region by a first distance.

9. The MIM capacitor of claim 5, wherein a top surface of the upper metal pattern has a step that is spaced apart from the boundary between the capacitor region and the peripheral region and into the peripheral region by a second distance which is greater than the first distance.

10. An electronic device comprising:
a first P-channel MOS transistor having a gate electrode connected to a gate voltage input terminal, a source terminal connected to an input voltage terminal, and a drain terminal connected to a first node;
a first N-channel MOS transistor having a gate electrode connected to the gate voltage input terminal, a source terminal connected to an output voltage terminal, and a drain terminal connected to the first node;
a second P-channel MOS transistor having a gate electrode connected to the gate voltage input terminal, a drain terminal connected to a second node, and a source terminal connected to the output voltage terminal;
a second N-channel MOS transistor having a gate electrode connected to the gate voltage input terminal, a drain terminal connected to the second node, and a source terminal connected to a ground terminal; and
a capacitor coupled between the first node and the second node,
wherein the capacitor includes:
an insulation pattern on an underlying structure having a capacitor region and a peripheral region surrounding the capacitor region, the insulation pattern having a plurality contact holes that expose portions of the underlying structure in the capacitor region;
a lower metal pattern in the capacitor region and covering a top surface of the insulation pattern, sidewalls of the insulation pattern corresponding to sidewalls of the contact holes, and the portions of the underlying structure exposed by the contact holes;
a dielectric pattern that covers the lower metal pattern in the capacitor region and a top surface of the insulation pattern in the peripheral region; and
an upper metal pattern on the dielectric pattern in the capacitor region and the peripheral region.

11. The electronic device of claim 10,
wherein the lower metal pattern is not on a top surface of the insulation pattern in the peripheral region,
wherein the dielectric pattern extends from a boundary between a capacitor region and the peripheral region and into the peripheral region by a first predetermined distance, and
wherein the upper metal pattern extends from the boundary between the capacitor region and the peripheral region and into the peripheral region by a second predetermined distance.

12. An electronic device comprising:
a first complementary metal-oxide-semiconductor (CMOS) inverter on a first region of a substrate and including a first P-channel MOS transistor and a first N-channel MOS transistor;
a second CMOS inverter on the first region of the substrate and including a second P-channel MOS transistor and a second N-channel MOS transistor;
an insulation layer on the substrate and covering the first and second CMOS inverters; and
a capacitor on a first interconnection pattern that is electrically coupled to the first and second CMOS inverters and in the insulation layer, in a second region of the substrate,
wherein the capacitor includes:
an insulation pattern on an underlying structure having a capacitor region and a peripheral region surrounding the capacitor region, the insulation pattern having a plurality contact holes that expose portions of the underlying structure in the capacitor region;
a lower metal pattern in the capacitor region to cover a top surface of the insulation pattern, sidewalls of the insulation pattern corresponding to sidewalls of the contact holes, and the portions of the underlying structure exposed by the contact holes;
a dielectric pattern covering the lower metal pattern in the capacitor region and a top surface of the insulation pattern in the peripheral region; and
an upper metal pattern on the dielectric pattern in the capacitor region and the peripheral region, and
wherein a drain terminal and a source terminal of the first P-channel MOS transistor are respectively connected to the first interconnection pattern and an input voltage terminal;
wherein a drain terminal and a source terminal of the first N-channel MOS transistor are respectively connected to the first interconnection pattern and an output voltage terminal;
wherein a source terminal and a drain terminal of the second P-channel MOS transistor are respectively connected to the output voltage terminal and the upper metal pattern of the capacitor;
wherein a source terminal and a drain terminal of the second N-channel MOS transistor are respectively connected to a ground terminal and the upper metal pattern of the capacitor; and
wherein gate electrodes of the first and second P-channel MOS transistors and gate electrodes of the first and second N-channel MOS transistors are electrically connected to a gate voltage input terminal.

13. The electronic device of claim 12,
wherein the lower metal pattern is not on a top surface of the insulation pattern in the peripheral region,
wherein the dielectric pattern extends from a boundary between a capacitor region and the peripheral region and into the peripheral region by a first predetermined distance, and
wherein the upper metal pattern extends from the boundary between the capacitor region and the peripheral region and into the peripheral region by a second predetermined distance.

14. An electronic device comprising:
a first complementary metal-oxide-semiconductor (CMOS) inverter including a first P-channel MOS transistor and a first N-channel MOS transistor formed on a substrate;
a second CMOS inverter including a second P-channel MOS transistor and a second N-channel MOS transistor formed on the substrate; and
an insulation layer on the substrate and covering the first and second CMOS inverters;
a capacitor on a first interconnection pattern that is electrically coupled to the first and second CMOS inverters and in the insulation layer,
wherein the capacitor includes:
an insulation pattern on an underlying structure having a capacitor region and a peripheral region surrounding the capacitor region, the insulation pattern having a plurality contact holes that expose portions of the underlying structure in the capacitor region;
a lower metal pattern in the capacitor region to cover a top surface of the insulation pattern, sidewalls of the insulation pattern corresponding to sidewalls of the contact holes, and the portions of the underlying structure exposed by the contact holes;
a dielectric pattern that covers the lower metal pattern in the capacitor region and a top surface of the insulation pattern in the peripheral region; and
an upper metal pattern on the dielectric pattern in the capacitor region and the peripheral region, and
wherein a drain terminal and a source terminal of the first P-channel MOS transistor are respectively connected to the first interconnection pattern and an input voltage terminal;
wherein a drain terminal and a source terminal of the first N-channel MOS transistor are respectively connected to the first interconnection pattern and an output voltage terminal;
wherein a source terminal and a drain terminal of the second P-channel MOS transistor are respectively connected to the output voltage terminal and the upper metal pattern of the capacitor;
wherein a source terminal and a drain terminal of the second N-channel MOS transistor are respectively connected to a ground terminal and the upper metal pattern of the capacitor; and
wherein gate electrodes of the first and second P-channel MOS transistors and gate electrodes of the first and second N-channel MOS transistors are electrically connected to a gate voltage input terminal.

15. The electronic device of claim 14,
wherein the lower metal pattern is not on a top surface of the insulation pattern in the peripheral region,
wherein the dielectric pattern extends from a boundary between a capacitor region and the peripheral region and into the peripheral region by a first predetermined distance, and
wherein the upper metal pattern extends from the boundary between the capacitor region and the peripheral region and into the peripheral region by a second predetermined distance.

16. A method of fabricating a metal-insulator-metal (MIM) capacitor, the method comprising:
forming an insulation pattern on an underlying structure having a capacitor region and a peripheral region surrounding the capacitor region, wherein the insulation pattern is has a plurality of contact holes exposing portions of the underlying structure;
forming a lower metal pattern on a top surface of the insulation pattern, the portions of the underlying structure exposed by the contact holes, and sidewalls of the underlying structure exposed by the contact holes;
forming a dielectric layer on the lower metal pattern in the capacitor region, and on a top surface of the insulation pattern in the peripheral region;
forming an upper metal layer on the dielectric layer; and
sequentially patterning the upper metal layer and the dielectric layer to form an upper metal pattern and a dielectric pattern.

17. The method of claim 16, wherein the lower metal pattern is not on a top surface of the insulation pattern in the peripheral region.

18. The method of claim 16, wherein the dielectric pattern covers the lower metal pattern in the capacitor region and extends from a boundary between the capacitor region and the peripheral region and into the peripheral region by a predetermined distance.

19. The method of claim 16, wherein the upper metal pattern is formed on the dielectric pattern in the capacitor region to extend from a boundary between the capacitor region and the peripheral region and into the peripheral region by the predetermined distance.
